(19) United States
(12) Patent Application Publication
(10) Pub. No.: US 2024/0170517 A1
(43) Pub. Date: May 23, 2024

(54) SOLID-STATE IMAGING ELEMENT AND ELECTRONIC DEVICE

(71) Applicant: SONY SEMICONDUCTOR SOLUTIONS CORPORATION, KANAGAWA (JP)

(72) Inventors: KEIJI NISHIDA, KANAGAWA (JP); KOJI SEKIGUCHI, KANAGAWA (JP)

(21) Appl. No.: 18/551,264

(22) PCT Filed: Feb. 15, 2022
(86) PCT No.: PCT/JP2022/005787

§ 371 Date: Sep. 19, 2023

(30) Foreign Application Priority Data
Mar. 30, 2021 (JP) 2021-058633

(51) Int. Cl. H01L 27/146

(52) U.S. Cl. CPC H01L 27/14625; H01L 27/14645

(57) ABSTRACT

A solid-state imaging element (1) according to the present disclosure includes a plurality of light-receiving pixels (11) arranged in a matrix inside a semiconductor layer (20). The light-receiving pixel (11) includes a pair of photoelectric conversion units, a first separation region (24), a second separation region (25), and a third separation region (26). The pair of photoelectric conversion units are disposed adjacent to each other. The first separation region (24) is disposed so as to surround the pair of photoelectric conversion units and is disposed so as to penetrate the semiconductor layer (20). The second separation region (25) is disposed between the pair of photoelectric conversion units and is disposed so as to penetrate the semiconductor layer (20). The third separation region (26) is disposed in a region surrounded by the first separation region (24) and is disposed from a light incident surface (20a) of the semiconductor layer (20) to a middle of the semiconductor layer (20).

### FIELD

The present disclosure relates to a solid-state imaging element and an electronic device.

### BACKGROUND

In recent years, in a back irradiation type complementary metal oxide semiconductor (CMOS) image sensor, there is a technique of causing light to be incident on a pair of photodiodes from the same on-chip lens to detect a phase difference (see, for example, Patent Literature 1).

### CITATION LIST

### Patent Literature

Patent Literature 1: US 2018/0219040 A

### SUMMARY

### Technical Problem

However, in the above-described conventional technique, by causing light to be incident on the pair of photodiodes from the same on-chip lens, the incident light may be largely scattered in a separation region disposed between the pair of photodiodes, and non-uniform color mixing may occur.

Therefore, the present disclosure proposes a solid-state imaging element and an electronic device capable of improving non-uniformity of color mixing.

### Solution to Problem

According to the present disclosure, there is provided a solid-state imaging element. The solid-state imaging element includes a plurality of light-receiving pixels arranged in a matrix inside a semiconductor layer. The light-receiving pixel includes a pair of photoelectric conversion units, a first separation region, a second separation region, and a third separation region. The pair of photoelectric conversion units are disposed adjacent to each other. The first separation region is disposed so as to surround the pair of photoelectric conversion units and is disposed so as to penetrate the semiconductor layer. The second separation region is disposed between the pair of photoelectric conversion units and is disposed so as to penetrate the semiconductor layer. The third separation region is disposed in a region surrounded by the first separation region and is disposed from a light incident surface of the semiconductor layer to a middle of the semiconductor layer.

### BRIEF DESCRIPTION OF DRAWINGS

FIG. 1 is a system configuration diagram illustrating a schematic configuration example of a solid-state imaging element according to embodiments of the present disclosure.

FIG. 2 is a plan view for explaining an arrangement example of a light-receiving pixel and an on-chip lens of a pixel array unit according to a first embodiment of the present disclosure.

FIG. 3 is a cross-sectional view taken along line A-A illustrated in FIG. 2 as viewed in the direction of the arrow.

FIG. 4 is a cross-sectional view taken along line B-B illustrated in FIG. 2 as viewed in the direction of the arrow.

FIG. 5 is a plan view for explaining an arrangement example of a light-receiving pixel and an on-chip lens of a pixel array unit according to Modification 1 of the first embodiment of the present disclosure.

FIG. 6 is a plan view for explaining an arrangement example of a light-receiving pixel and an on-chip lens of a pixel array unit according to Modification 2 of the first embodiment of the present disclosure.

FIG. 7 is a cross-sectional view taken along line C-C illustrated in FIG. 6 as viewed in the direction of the arrow.

FIG. 8 is a plan view for explaining an arrangement example of a light-receiving pixel and an on-chip lens of a pixel array unit according to Modification 3 of the first embodiment of the present disclosure.

FIG. 9 is a plan view for explaining an arrangement example of a light-receiving pixel and an on-chip lens of a pixel array unit according to Modification 4 of the first embodiment of the present disclosure.

FIG. 10 is a plan view for explaining an arrangement example of light-receiving pixels and third separation regions of a pixel array unit according to Modification 5 of the first embodiment of the present disclosure.

FIG. 11 is a diagram illustrating an example of a process of manufacturing the light-receiving pixel according to the first embodiment of the present disclosure.

FIG. 12 is a diagram illustrating an example of the process of manufacturing the light-receiving pixel according to the first embodiment of the present disclosure.

FIG. 13 is a diagram illustrating an example of the process of manufacturing the light-receiving pixel according to the first embodiment of the present disclosure.

FIG. 14 is a diagram illustrating an example of the process of manufacturing the light-receiving pixel according to the first embodiment of the present disclosure.

FIG. 15 is a diagram illustrating an example of the process of manufacturing the light-receiving pixel according to the first embodiment of the present disclosure.

FIG. 16 is a diagram illustrating an example of the process of manufacturing the light-receiving pixel according to the first embodiment of the present disclosure.

FIG. 17 is a diagram illustrating an example of the process of manufacturing the light-receiving pixel according to the first embodiment of the present disclosure.

FIG. 18 is a diagram illustrating an example of the process of manufacturing the light-receiving pixel according to the first embodiment of the present disclosure.

FIG. 19 is a plan view for explaining an arrangement example of light-receiving pixels of a pixel array unit according to a second embodiment of the present disclosure.

FIG. 20 is a plan view for explaining an arrangement example of the light-receiving pixel and an on-chip lens of the pixel array unit according to the second embodiment of the present disclosure.

FIG. 21 is a cross-sectional view taken along line D-D illustrated in FIG. 20 as viewed in the direction of the arrow.

FIG. 22 is a cross-sectional view for explaining a state of light incident on a light-receiving pixel in a reference example of the present disclosure.

FIG. 23 is a cross-sectional view for explaining a state of light incident on the light-receiving pixel according to the second embodiment of the present disclosure.

FIG. 24 is a plan view for explaining another arrangement example of the light-receiving pixel and the on-chip lens of the pixel array unit according to the second embodiment of the present disclosure.

FIG. 25 is a plan view for explaining another arrangement example of the light-receiving pixel and the on-chip lens of the pixel array unit according to the second embodiment of the present disclosure.

FIG. 26 is a plan view for explaining another arrangement example of the light-receiving pixel and the on-chip lens of the pixel array unit according to the second embodiment of the present disclosure.

FIG. 27 is a plan view for explaining an arrangement example of a light-receiving pixel and an on-chip lens of a pixel array unit according to Modification 1 of the second embodiment of the present disclosure.

FIG. 28 is a plan view for explaining an arrangement example of a light-receiving pixel and an on-chip lens of a pixel array unit according to Modification 2 of the second embodiment of the present disclosure.

FIG. 29 is a plan view for explaining an arrangement example of a light-receiving pixel and an on-chip lens of a pixel array unit according to Modification 3 of the second embodiment of the present disclosure.

FIG. 30 is a plan view for explaining an arrangement example of a light-receiving pixel and an on-chip lens of a pixel array unit according to Modification 4 of the second embodiment of the present disclosure.

FIG. 31 is a plan view for explaining an arrangement example of a light-receiving pixel and an on-chip lens of a pixel array unit according to Modification 5 of the second embodiment of the present disclosure.

FIG. 32 is a plan view for explaining an arrangement example of a light-receiving pixel and an on-chip lens of a pixel array unit according to Modification 6 of the second embodiment of the present disclosure.

FIG. 33 is a plan view for explaining an arrangement example of a light-receiving pixel and an on-chip lens of a pixel array unit according to Modification 7 of the second embodiment of the present disclosure.

FIG. 34 is a plan view for explaining an arrangement example of a light-receiving pixel and an on-chip lens of a pixel array unit according to Modification 8 of the second embodiment of the present disclosure.

FIG. 35 is a plan view for explaining an arrangement example of a light-receiving pixel and an on-chip lens of a pixel array unit according to Modification 9 of the second embodiment of the present disclosure.

FIG. 36 is a block diagram illustrating a configuration example of an imaging device as an electronic device to which the technique according to the present disclosure is applied.

### DESCRIPTION OF EMBODIMENTS

Hereinafter, embodiments of the present disclosure will be described in detail with reference to the drawings. Note that in the following embodiments, the same portion is denoted by the same reference numeral, and redundant description will be omitted.

In recent years, in a back irradiation type complementary metal oxide semiconductor (CMOS) image sensor, there is a technique of causing light to be incident on a pair of photodiodes from the same on-chip lens to detect a phase difference.

However, in the above-described conventional technique, by causing light to be incident on the pair of photodiodes from the same on-chip lens, the incident light may be largely scattered in a separation region disposed between the pair of photodiodes. Then, the largely scattered light is incident on another photodiode, and color mixing may thereby occur in the pixel array unit.

In addition, occurrence of such color mixing is particularly significant in another photodiode adjacent in a direction perpendicular to a direction in which the separation region extends. That is, in the above-described conventional technique, color mixing may occur non-uniformly in a plurality of photodiodes disposed around the pair of photodiodes.

Therefore, implementation of a technique capable of overcoming the above-described problems and improving non-uniformity of color mixing is expected.

### Configuration of Solid-State Imaging Element

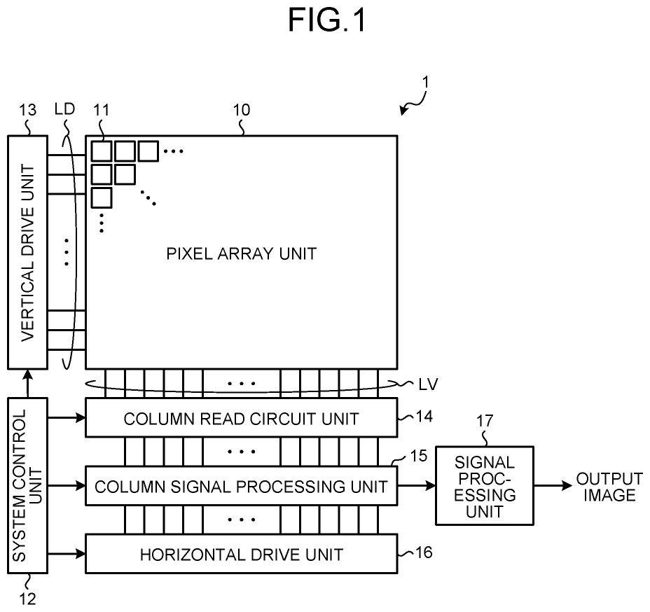

FIG. 1 is a system configuration diagram illustrating a schematic configuration example of a solid-state imaging element 1 according to embodiments of the present disclosure. As illustrated in FIG. 1, the solid-state imaging element 1 that is a CMOS image sensor includes a pixel array unit 10, a system control unit 12, a vertical drive unit 13, a column read circuit unit 14, a column signal processing unit 15, a horizontal drive unit 16, and a signal processing unit 17.

The pixel array unit 10, the system control unit 12, the vertical drive unit 13, the column read circuit unit 14, the column signal processing unit 15, the horizontal drive unit 16, and the signal processing unit 17 are disposed on the same semiconductor substrate or on a plurality of electrically connected laminated semiconductor substrates.

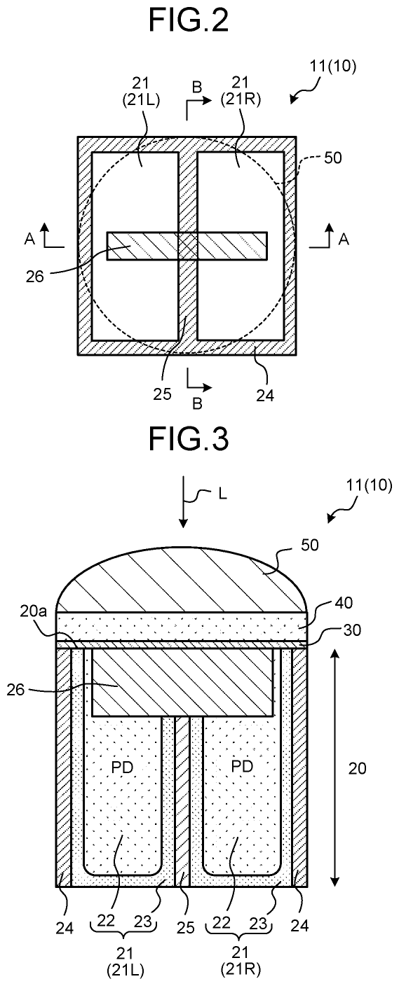

In the pixel array unit 10, light-receiving pixels 11 each having a photoelectric conversion element (photodiode 21 (see FIG. 2)) capable of photoelectrically converting a charge amount corresponding to an incident light amount, accumulating the photoelectrically converted charge amount therein, and outputting the photoelectrically converted charge amount as a signal are two-dimensionally arranged in a matrix.

In addition, in addition to the light-receiving pixels 11, the pixel array unit 10 may include a region in which a dummy pixel not including the photodiode 21, a light-shielding pixel in which incidence of light coming from the outside is blocked by shielding a light-receiving surface from light, and the like are arranged in a row and/or a column. Note that the light-shielding pixel may have a configuration similar to the light-receiving pixel 11 except that the light-shielding pixel has a light-receiving surface shielded from light. In addition, hereinafter, a photocharge of a charge amount corresponding to the amount of incident light is also simply referred to as “charge”, and the light-receiving pixel 11 may also be simply referred to as “pixel”.

In the pixel array unit 10, for the pixel array in a matrix, a pixel drive line LD is formed for each row in the left-right direction in the drawing (pixel array direction in a pixel row), and a vertical pixel line LV is formed for each column in the up-down direction in the drawing (pixel array direction in a pixel column). One end of the pixel drive line LD is connected to an output terminal corresponding to each row of the vertical drive unit 13.

The column read circuit unit 14 includes at least a circuit that supplies a constant current to the light-receiving pixels 11 in a selected row in the pixel array unit 10 for each column, a current mirror circuit, a changeover switch of the light-receiving pixel 11 to be read, and the like.

The column read circuit unit 14 constitutes an amplifier together with a transistor in a selected pixel in the pixel array unit 10, converts a photocharge signal into a voltage signal, and outputs the voltage signal to the vertical pixel line LV.

The vertical drive unit 13 includes a shift register, an address decoder, and the like, and drives the light-receiving pixels 11 of the pixel array unit 10, for example, at the same time for all the pixels or row by row. Although a specific configuration of the vertical drive unit 13 is not illustrated, the vertical drive unit 13 has a configuration including a read scanning system and a sweep scanning system or a batch sweep and a batch transfer system.

The read scanning system sequentially selects and scans the light-receiving pixels 11 of the pixel array unit 10 row by row in order to read a pixel signal from the light-receiving pixels 11. In a case of row driving (rolling shutter operation), as for sweep, sweep scanning is performed on a read row on which read scanning is performed by the read scanning system prior to the read scanning by a time corresponding to a shutter speed.

In addition, in a case of global exposure (global shutter operation), batch sweep is performed prior to batch transfer by a time corresponding to a shutter speed. By such sweep, unnecessary charges are swept (reset) from the photodiodes 21 of the light-receiving pixels 11 in the read row. Then, a so-called electronic shutter operation is performed by sweeping (resetting) unnecessary charges.

Here, the electronic shutter operation refers to an operation of discarding unnecessary photocharges accumulated in the photodiode 21 until immediately before and newly starting exposure (starting accumulation of photocharges).

A signal read by the read operation performed by the read scanning system corresponds to the amount of light incident after the immediately preceding read operation or the electronic shutter operation. In the case of row driving, a period from a read timing by the immediately preceding read operation or a sweep timing by the electronic shutter operation to a read timing by the current read operation is a photocharge accumulation time (exposure time) in the light-receiving pixel 11. In the case of global exposure, a period from batch sweep to batch transfer is the accumulation time (exposure time).

The pixel signal output from each of the light-receiving pixels 11 in the pixel row selected and scanned by the vertical drive unit 13 is supplied to the column signal processing unit 15 through each of the vertical pixel lines LV. The column signal processing unit 15 performs predetermined signal processing on the pixel signal output from each of the light-receiving pixels 11 in the selected row through the vertical pixel line LV for each pixel column of the pixel array unit 10, and temporarily holds the pixel signal after the signal processing.

Specifically, the column signal processing unit 15 performs at least noise removal processing, for example, correlated double sampling (CDS) processing as the signal processing. By the CDS processing performed by the column signal processing unit 15, fixed pattern noise unique to pixels, such as reset noise or threshold variation of an amplification transistor AMP is removed.

Note that the column signal processing unit 15 can be configured to have, for example, an AD conversion function in addition to the noise removal processing and to output the pixel signal as a digital signal.

The horizontal drive unit 16 includes a shift register, an address decoder, and the like, and sequentially selects a unit circuit corresponding to a pixel column of the column signal processing unit 15. By selection and scanning performed by the horizontal drive unit 16, the pixel signals that have been subjected to the signal processing by the column signal processing unit 15 are sequentially output to the signal processing unit 17.

The system control unit 12 includes a timing generator that generates various timing signals, and the like, and performs drive control of the vertical drive unit 13, the column signal processing unit 15, the horizontal drive unit 16, and the like on the basis of various timing signals generated by the timing generator.

The solid-state imaging element 1 further includes the signal processing unit 17 and a data storage unit (not illustrated). The signal processing unit 17 has at least an addition processing function, and performs various types of signal processing such as addition processing on a pixel signal output from the column signal processing unit 15.

The data storage unit temporarily stores data necessary for signal processing in the signal processing unit 17. The signal processing unit 17 and the data storage unit may be processing performed by an external signal processing unit disposed on a substrate different from a substrate where the solid-state imaging element 1 is disposed, for example, a digital signal processor (DSP) or software, or may be mounted on the same substrate as the substrate where the solid-state imaging element 1 is disposed.

### First Embodiment

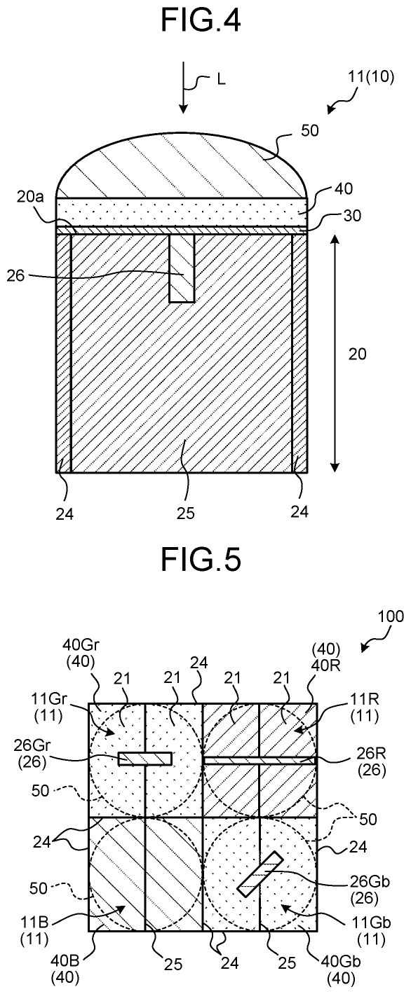

Next, a detailed configuration of the pixel array unit 10 according to the first embodiment will be described with reference to FIGS. 2 to 4. FIG. 2 is a plan view for explaining an arrangement example of the light-receiving pixel 11 and an on-chip lens 50 of the pixel array unit 10 according to the first embodiment of the present disclosure. FIG. 3 is a cross-sectional view taken along line A-A illustrated in FIG. 2 as viewed in the direction of the arrow, and FIG. 4 is a cross-sectional view taken along line B-B illustrated in FIG. 2 as viewed in the direction of the arrow.

As illustrated in FIG. 3 and the like, the pixel array unit 10 includes a semiconductor layer 20, a planarizing film 30, a color filter 40, and the on-chip lens 50.

The semiconductor layer 20 contains, for example, silicon. The semiconductor layer 20 includes a plurality of photodiodes (PD) 21. The photodiode 21 is an example of a photoelectric conversion unit. Note that one light-receiving pixel 11 includes a pair of photodiodes 21 (hereinafter, also referred to as photodiodes 21L and 21R). In addition, the light-receiving pixel 11 has a substantially square shape in plan view, and the photodiode 21 has a substantially rectangular shape in plan view.

The photodiode 21 includes a first impurity region 22 containing a first conductivity type (for example, N type) impurity and a second impurity region 23 containing a second conductivity type (for example, P type) impurity.

The first impurity region 22 is disposed in a central portion of the photodiode 21, and the second impurity region 23 is disposed along a side portion and a bottom portion (a portion on a side opposite to a side on which light L is incident) of the first impurity region 22.

In addition, the light-receiving pixel 11 includes a first separation region 24, a second separation region 25, and a third separation region 26. As illustrated in FIG. 2, the first separation region 24 is disposed so as to surround the pair of photodiodes 21 in one light-receiving pixel 11.

In addition, as illustrated in FIGS. 3 and 4, the first separation region 24 is disposed so as to penetrate the semiconductor layer 20. The first separation region 24 is made of, for example, a dielectric having a low refractive index, such as silicon oxide (SiO₂). As a result, the first separation region 24 can optically and electrically separate the plurality of light-receiving pixels 11 adjacent to each other.

As illustrated in FIG. 2, the second separation region 25 is disposed between the pair of photodiodes 21 adjacent to each other in one light-receiving pixel 11. In addition, as illustrated in FIG. 4, the second separation region 25 is disposed so as to penetrate the semiconductor layer 20.

The second separation region 25 is made of, for example, a dielectric having a low refractive index, such as silicon oxide. As a result, the second separation region 25 can optically and electrically separate the plurality of photodiodes 21 adjacent to each other.

As described above, in the first embodiment, since the pair of photodiodes 21 can be separated from each other using the second separation region 25, a phase difference of incident light L can be detected using the pair of photodiodes 21.

Meanwhile, by the second separation region 25 being disposed in the light-receiving pixel 11, light L incident on an end portion on a light incident side in the second separation region 25 is largely scattered by a large refractive index difference from the photodiode 21. Then, the largely scattered light L is incident on another light-receiving pixel 11, and color mixing may thereby occur in the pixel array unit 10.

In addition, occurrence of such color mixing is particularly significant in another light-receiving pixel 11 adjacent in a direction (left-right direction in FIG. 2) perpendicular to a direction in which the second separation region 25 extends. That is, due to the second separation region 25, color mixing may occur non-uniformly in a plurality of light-receiving pixels 11 disposed around a light-receiving pixel 11.

Therefore, in the first embodiment, the non-uniformity of color mixing in the pixel array unit 10 is improved by disposing the third separation region 26 in the light-receiving pixel 11.

Specifically, as illustrated in FIG. 2, the third separation region 26 is disposed in a region surrounded by the first separation region 24. In addition, the third separation region 26 is disposed in a direction (left-right direction in FIG. 2) different from a direction (up-down direction in FIG. 2) in which the second separation region 25 extends in plan view.

In addition, as illustrated in FIGS. 3 and 4, the third separation region 26 is disposed from a light incident surface 20a of the semiconductor layer 20 to a middle of the semiconductor layer 20 (that is, so as not to penetrate the semiconductor layer 20). The third separation region 26 is made of, for example, the same material (a dielectric having a low refractive index) as that of the second separation region 25.

By disposing such a third separation region 26 in the light-receiving pixel 11, light L can be scattered also in a direction different from the second separation region 25. Therefore, according to the first embodiment, the non-uniformity of color mixing in the pixel array unit 10 can be improved.

In addition, in the first embodiment, the third separation region 26 is preferably disposed so as to straddle the second separation region 25 in plan view. As a result, since a large amount of light L can be scattered in a direction different from the second separation region 25 in plan view, the non-uniformity of color mixing in the pixel array unit 10 can be further improved.

In addition, in the first embodiment, the third separation region 26 is preferably made of the same material (for example, silicon oxide) as that of the first separation region 24 and the second separation region 25. As a result, in a process of manufacturing the light-receiving pixel 11 described later, the third separation region 26 can be formed in the same step as the first separation region 24 and the second separation region 25.

Therefore, according to the first embodiment, since the process of manufacturing the pixel array unit 10 can be simplified, cost of manufacturing the solid-state imaging element 1 can be reduced.

Meanwhile, in the first embodiment, the third separation region 26 may be made of a material different from that of the first separation region 24 and the second separation region 25. For example, the third separation region 26 may be made of a material (for example, tantalum oxide (Ta₂O₅) or titanium oxide (TiO₂)) having a higher refractive index than that of the first separation region 24 and the second separation region 25.

As a result, since the degree of scattering of light L by the third separation region 26 can be variously controlled, the non-uniformity of color mixing in the pixel array unit 10 can be improved.

In addition, in the first embodiment, the third separation region 26 is preferably disposed so as not to penetrate the semiconductor layer 20. This can suppress the volume of the photodiode 21 from being reduced by the third separation region 26.

Therefore, according to the first embodiment, it is possible to suppress a saturation signal charge amount of the photodiode 21 from being reduced by the third separation region 26. Furthermore, in the first embodiment, by disposing the third separation region 26 so as not to penetrate the semiconductor layer 20, it is possible to suppress the photodiodes 21 from being electrically separated from each other by the third separation region 26.

Description of other portions in the pixel array unit 10 will be continued. The planarizing film 30 is disposed on the light incident surface 20a of the semiconductor layer 20, and planarizes the light incident surface 20a. The planarizing film 30 is made of, for example, silicon oxide.

Note that, in the first embodiment, a fixed charge film (not illustrated) may be disposed between the photodiode 21 and each of the first separation region 24, the second separation region 25, and the planarizing film 30. Such a fixed charge film has a function of fixing a charge (here, a positive hole) to an interface between the photodiode 21 and each of the first separation region 24, the second separation region 25, and the planarizing film 30.

As a material of the fixed charge film, a high dielectric material having a large amount of fixed charges is preferably used. The fixed charge film is made of, for example, hafnium oxide (HfO₂), aluminum oxide (Al₂O₃), tantalum oxide, zirconium oxide (ZrO₂), titanium oxide, magnesium oxide (MgO₂), or lanthanum oxide (La₂O₃).

In addition, the fixed charge film may be made of praseodymium oxide (Pr₂O₃) , cerium oxide (CeO₂) , neodymium oxide (Nd₂O₃) , promethium oxide (Pm₂O₃) , samarium oxide (Sm₂O₃), europium oxide (Eu₂O₃), or the like.

In addition, the fixed charge film may be made of gadolinium oxide (Gd₂O₃), terbium oxide (Tb₂O₃), dysprosium oxide (Dy₂O₃), holmium oxide (Ho₂O₃), erbium oxide (Er₂O₃), thulium oxide (Tm₂O₃), or the like.

In addition, the fixed charge film may be made of ytterbium oxide (Yb₂O₃), lutetium oxide (Lu₂O₃), yttrium oxide (Y₂O₃), aluminum nitride (AlN), hafnium oxynitride (HfON), an aluminum oxynitride film (AlON), or the like.

The color filter 40 is an optical filter that transmits light in a predetermined wavelength region among incident light beams L, and is disposed between the on-chip lens 50 and the planarizing film 30.

The on-chip lens 50 is disposed on a side where light L is incident on the semiconductor layer 20, and has a function of condensing light L toward a corresponding light-receiving pixel 11. The on-chip lens 50 is made of, for example, an organic material or silicon oxide.

In the first embodiment, as illustrated in FIG. 2 and the like, one on-chip lens 50 is disposed for one light-receiving pixel 11 (that is, one on-chip lens 50 is disposed for one pair of photodiodes 21).

### Various Modifications of First Embodiment

Next, various modifications of the first embodiment will be described with reference to FIGS. 5 to 10.

### Modification 1

FIG. 5 is a plan view for explaining an arrangement example of the light-receiving pixel 11 and the on-chip lens 50 of the pixel array unit 10 according to Modification 1 of the first embodiment of the present disclosure.

In Modification 1 of the first embodiment, as illustrated in FIG. 5, four light-receiving pixels 11 constitute one light-receiving pixel group 100. The light-receiving pixel group 100 includes a red pixel 11R having a color filter 40R, a green pixel 11Gr having a color filter 40Gr, a green pixel 11Gb having a color filter 40Gb, and a blue pixel 11B having a color filter 40B.

The color filter 40R is a color filter 40 that transmits light in a red wavelength region among incident light beams L, and the color filters 40Gr and 40Gb are color filters 40 that transmit light in a green wavelength region among incident light beams L. The color filter 40B is a color filter 40 that transmits light in a blue wavelength region among incident light beams L.

Furthermore, inside one light-receiving pixel group 100, the color filters 40R, 40Gr, 40Gb, and 40B are arranged in a regular color array (for example, Bayer array).

In addition, the red pixel 11R included in the light-receiving pixel group 100 receives red light that has passed through the color filter 40R, photoelectrically converts a charge amount corresponding to an incident light amount of the red light, and accumulates the photoelectrically converted charge amount inside the red pixel 11R.

Similarly, the green pixels 11Gr and 11Gb receive green light that has passed through the color filters 40Gr and 40Gb, photoelectrically converts a charge amount corresponding to an incident light amount of the green light, and accumulates the photoelectrically converted charge amount inside the green pixels 11Gr and 11Gb, respectively. In addition, the blue pixel 11B receives blue light that has passed through the color filter 40B, photoelectrically converts a charge amount corresponding to an incident light amount of the blue light, and accumulates the photoelectrically converted charge amount inside the blue pixel 11B.

As described above, in the light-receiving pixel group 100 according to Modification 1 of the first embodiment, light beams in two or more (three in the example of FIG. 5) wavelength regions are received by the individual light-receiving pixels 11, respectively.

In addition, in Modification 1 of the first embodiment, as illustrated in FIG. 5, the plurality of light-receiving pixels 11 included in the same light-receiving pixel group 100 include the third separation regions 26 having different shapes, respectively.

For example, as illustrated in FIG. 5, the red pixel 11R includes a third separation region 26R that is disposed so as to extend in a direction substantially perpendicular to the second separation region 25 in plan view and so as to extend from one side to the other side in the rectangular first separation region 24.

In addition, the green pixel 11Gr includes a third separation region 26Gr that is disposed so as to extend in a direction substantially perpendicular to the second separation region 25 in plan view and so as not to extend from one side to the other side in the rectangular first separation region 24.

In addition, the green pixel 11Gb includes a third separation region 26Gb that is disposed so as to extend in a direction obliquely intersecting with the second separation region 25 from the upper right to the lower left in plan view and so as not to extend from one side to the other side in the rectangular first separation region 24. Note that, in Modification 1 of the first embodiment, the third separation region 26 is not disposed in the blue pixel 11B.

As described above, since the plurality of light-receiving pixels 11 included in the same light-receiving pixel group 100 include the third separation regions 26 having various shapes, respectively, the degree of scattering of light L by each of the third separation regions 26 can be variously controlled. Therefore, according to Modification 1 of the first embodiment, the non-uniformity of color mixing in the pixel array unit 10 can be improved.

Note that, in Modification 1, the planar shape of the third separation region 26 disposed in each of the light-receiving pixels 11 is not limited to the example of FIG. 5, and the third separation region 26 may have various planar shapes.

### Modification 2

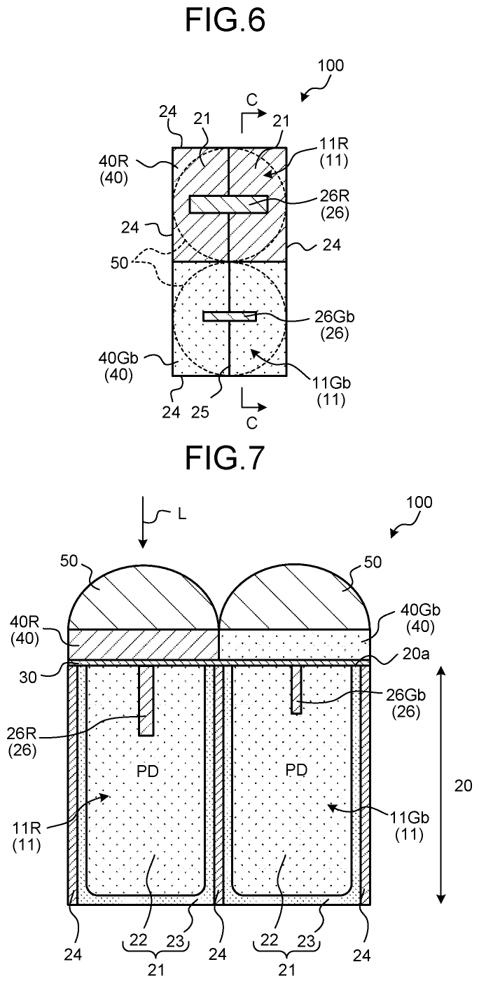

FIG. 6 is a plan view for explaining an arrangement example of the light-receiving pixel 11 and the on-chip lens 50 of the pixel array unit 10 according to Modification 2 of the first embodiment of the present disclosure, and FIG. 7 is a cross-sectional view taken along line C-C illustrated in FIG. 6 as viewed in the direction of the arrow.

In Modification 2 of the first embodiment, similarly to the above-described Modification 1, the plurality of light-receiving pixels 11 included in the same light-receiving pixel group 100 include the third separation regions 26 having different shapes, respectively.

In addition, as illustrated in FIG. 7, in Modification 2, in the same light-receiving pixel group 100, a third separation region 26 disposed in one light-receiving pixel 11 may be formed deeper than a third separation region 26 disposed in a different light-receiving pixel 11. For example, in the example of FIG. 7, the third separation region 26R disposed in the red pixel 11R is formed deeper than the third separation region 26Gb disposed in the green pixel 11Gb.

As described above, since the plurality of light-receiving pixels 11 included in the same light-receiving pixel group 100 include the third separation regions 26 having various depths, respectively, the degree of scattering of light L by each of the third separation regions 26 can be variously controlled. Therefore, according to Modification 2 of the first embodiment, the non-uniformity of color mixing in the pixel array unit 10 can be improved.

### Modification 3

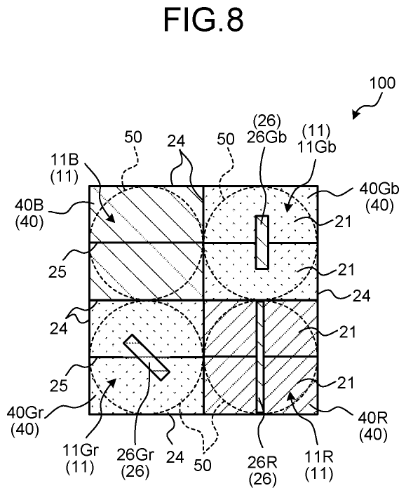

In the first embodiment and the various modifications described above, the case where the second separation region 25 is oriented in the up-down direction in plan view in the light-receiving pixel 11 has been described, but the present disclosure is not limited to such an example. FIG. 8 is a plan view for explaining an arrangement example of the light-receiving pixel 11 and the on-chip lens 50 of the pixel array unit 10 according to Modification 3 of the first embodiment of the present disclosure.

As illustrated in FIG. 8, in Modification 3 of the first embodiment, the second separation region 25 is oriented in the left-right direction in plan view in the light-receiving pixel 11.

In addition, in Modification 3, the third separation region 26 is disposed in a direction different from a direction in which the second separation region 25 extends in plan view. As a result, since light L can be scattered in a direction different from the second separation region 25, the non-uniformity of color mixing in the pixel array unit 10 can be improved.

Furthermore, in Modification 3, the plurality of light-receiving pixels 11 included in the same light-receiving pixel group 100 include the third separation regions 26 having different shapes, respectively.

For example, as illustrated in FIG. 8, the red pixel 11R includes a third separation region 26R that is disposed so as to extend in a direction (up-down direction in FIG. 8) substantially perpendicular to the second separation region 25 in plan view and so as to extend from one side to the other side in the rectangular first separation region 24.

In addition, the green pixel 11Gb includes a third separation region 26Gb that is disposed so as to extend in a direction (up-down direction in FIG. 8) substantially perpendicular to the second separation region 25 in plan view and so as not to extend from one side to the other side in the rectangular first separation region 24.

In addition, the green pixel 11Gr includes a third separation region 26Gr that is disposed so as to extend in a direction obliquely intersecting with the second separation region 25 from the upper left to the lower right in plan view and so as not to extend from one side to the other side in the rectangular first separation region 24. Note that, in Modification 3 of the first embodiment, the third separation region 26 is not disposed in the blue pixel 11B.

As described above, since the plurality of light-receiving pixels 11 included in the same light-receiving pixel group 100 include the third separation regions 26 having various shapes, respectively, the degree of scattering of light L by each of the third separation regions 26 can be variously controlled. Therefore, according to Modification 3 of the first embodiment, the non-uniformity of color mixing in the pixel array unit 10 can be further improved.

Note that, in Modification 3, the planar shape of the third separation region 26 disposed in each of the light-receiving pixels 11 is not limited to the example of FIG. 8, and the third separation region 26 may have various planar shapes.

### Modification 4

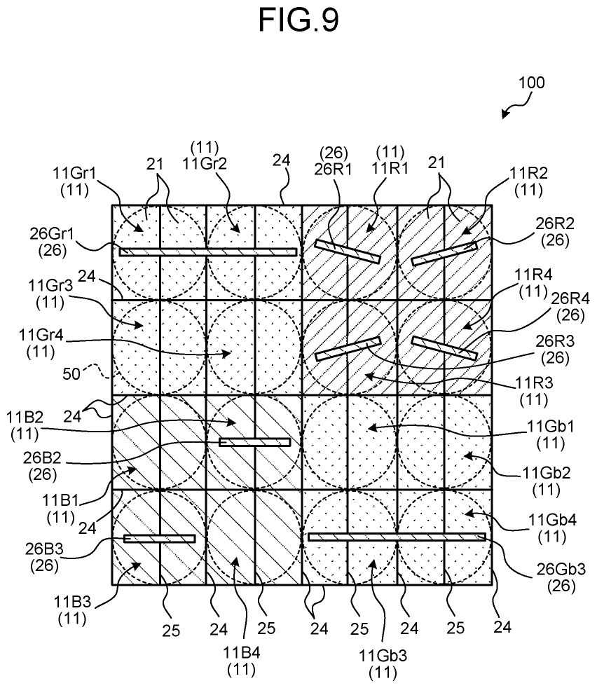

In Modifications 1 and 3 described above, the example in which four light-receiving pixels 11 constitute one light-receiving pixel group 100 has been described, but the present disclosure is not limited to such an example. FIG. 9 is a plan view for explaining an arrangement example of the light-receiving pixel 11 and the on-chip lens 50 of the pixel array unit 10 according to Modification 4 of the first embodiment of the present disclosure.

As illustrated in FIG. 8, in Modification 4 of the first embodiment, sixteen light-receiving pixels 11 constitute one light-receiving pixel group 100. Specifically, four green pixels 11Gr1 to 11Gr4 are arranged in two rows and two columns at the upper left of the light-receiving pixel group 100 in plan view. In addition, four red pixels 11R1 to 11R4 are arranged in two rows and two columns at the upper right of the light-receiving pixel group 100 in plan view.

In addition, four blue pixels 11B1 to 11B4 are arranged in two rows and two columns at the lower left of the light-receiving pixel group 100 in plan view. In addition, four green pixels 11Gb1 to 11Gb4 are arranged in two rows and two columns at the lower right of the light-receiving pixel group 100 in plan view.

In addition, in Modification 4 of the first embodiment, as illustrated in FIG. 9, the plurality of light-receiving pixels 11 that are included in the same light-receiving pixel group 100 and receive light of the same color include the third separation regions 26 having different shapes, respectively.

For example, as illustrated in FIG. 9, the green pixels 11Gr1 and 11Gr2 include a third separation region 26Gr1 that is disposed so as to extend in a direction substantially perpendicular to the second separation region 25 in plan view and so as to cross the green pixels 11Gr1 and 11Gr2.

In addition, the red pixel 11R1 includes a third separation region 26R1 that is disposed so as to extend in a direction obliquely intersecting with the second separation region 25 from the upper left to the lower right in plan view and so as not to extend from one side to the other side in the rectangular first separation region 24.

In addition, the red pixel 11R2 includes a third separation region 26R2 that is disposed so as to extend in a direction obliquely intersecting with the second separation region 25 from the upper right to the lower left in plan view and so as not to extend from one side to the other side in the rectangular first separation region 24.

In addition, the red pixel 11R3 includes a third separation region 26R3 that is disposed so as to extend in a direction obliquely intersecting with the second separation region 25 from the upper right to the lower left in plan view and so as not to extend from one side to the other side in the rectangular first separation region 24.

In addition, the green pixel 11R4 includes a third separation region 26R4 that is disposed so as to extend in a direction obliquely intersecting with the second separation region 25 from the upper left to the lower right in plan view and so as not to extend from one side to the other side in the rectangular first separation region 24.

In addition, the blue pixel 11B2 includes a third separation region 26B2 that is disposed so as to extend in a direction (left-right direction in FIG. 9) substantially perpendicular to the second separation region 25 in plan view and so as not to extend from one side to the other side in the rectangular first separation region 24.

In addition, the blue pixel 11B3 includes a third separation region 26B3 that is disposed so as to extend in a direction (left-right direction in FIG. 9) substantially perpendicular to the second separation region 25 in plan view and so as not to extend from one side to the other side in the rectangular first separation region 24.

In addition, the green pixels 11Gb3 and 11Gb4 include a third separation region 26Gb3 that is disposed so as to extend in a direction substantially perpendicular to the second separation region 25 in plan view and so as to cross the green pixels 11Gb3 and 11Gb4.

As described above, since the plurality of light-receiving pixels 11 that are included in the same light-receiving pixel group 100 and receive light of the same color include the third separation regions 26 having various shapes, respectively, the degree of scattering of light L by each of the third separation regions 26 can be variously controlled. Therefore, according to Modification 4 of the first embodiment, the non-uniformity of color mixing in the pixel array unit 10 can be further improved.

Note that, in Modification 4, the planar shape of the third separation region 26 disposed in each of the light-receiving pixels 11 is not limited to the example of FIG. 9, and the third separation region 26 may have various planar shapes.

### Modification 5

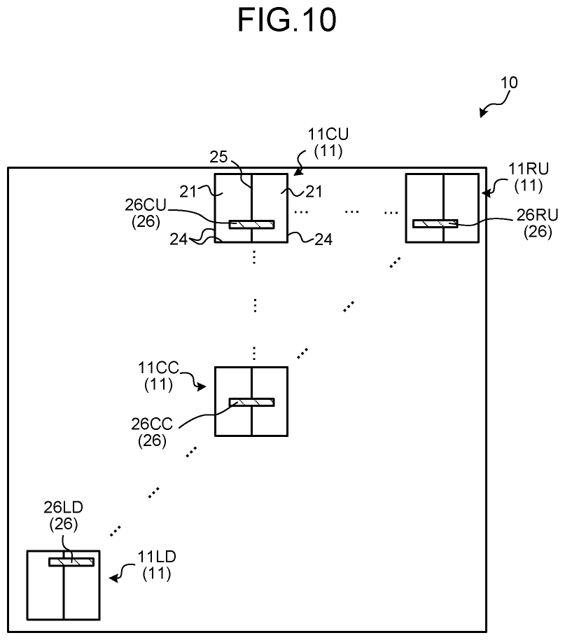

FIG. 10 is a plan view for explaining an arrangement example of the light-receiving pixels 11 and the third separation regions 26 of the pixel array unit 10 according to Modification 5 of the first embodiment of the present disclosure.

In the pixel array unit 10 including a large number of light-receiving pixels 11, a light-receiving pixel 11CC located at a central portion and a light-receiving pixel 11 (for example, a light-receiving pixel 11RU at an upper right corner) located at an end portion have different incident angles of light L coming from the on-chip lens 50.

As a result, in the light-receiving pixel 11 at the end portion, a light scattering state by the third separation region 26 is different from that in the light-receiving pixel 11CC located at the central portion. That is, in the pixel array unit 10, the light scattering state by the third separation region 26 is different between the light-receiving pixels 11 having different image heights.

Here, “image height” refers to a distance from an optical axis (for example, the center of the pixel array unit 10). In a case where the optical axis is the center of the pixel array unit 10, such a center is expressed as, for example, “the image height is low” or “image height center”, and an end portion of the pixel array unit 10 is expressed as, for example, “the image height is high” or “high image height”.

In Modification 5 of the first embodiment, the position and shape of the third separation region 26 are changed depending on the image height of the light-receiving pixel 11 on the pixel array unit 10. For example, in Modification 5, as illustrated in FIG. 10, in the plurality of light-receiving pixels 11 having different image heights, the third separation regions 26 having different positions and/or different shapes are disposed, respectively.

For example, the light-receiving pixel 11CC at the image height center includes a third separation region 26CC whose center of gravity is disposed at a position substantially equal to the center of gravity of the light-receiving pixel 11CC. Meanwhile, the light-receiving pixel 11RU located at an upper right end portion of the pixel array unit 10 includes a third separation region 26RU whose center of gravity is disposed at a position shifted to the lower left from the center of gravity of the light-receiving pixel 11RU.

In addition, a light-receiving pixel 11CU located at an upper central end portion of the pixel array unit 10 includes a third separation region 26CU whose center of gravity is disposed at a position shifted downward from the center of gravity of the light-receiving pixel 11CU. In addition, a light-receiving pixel 11LD located at a lower left end portion of the pixel array unit 10 includes a third separation region 26LC whose center of gravity is disposed at a position shifted to the upper right from the center of gravity of the light-receiving pixel 11LD.

As described above, in the plurality of light-receiving pixels 11 having different image heights, the third separation region 26 having different positions are disposed, respectively. Therefore, the degree of scattering of light L by each of the third separation regions 26 can be variously controlled. Therefore, according to Modification 5 of the first embodiment, the non-uniformity of color mixing in the pixel array unit 10 can be further improved.

Note that, in the example of FIG. 10, the example in which the position of the third separation region 26 is changed depending on the image height on the pixel array unit 10 has been described. However, the shape of the third separation region 26 may be changed, or both the position and the shape of the third separation region 26 may be changed depending on the image height on the pixel array unit 10.

### Manufacturing Process

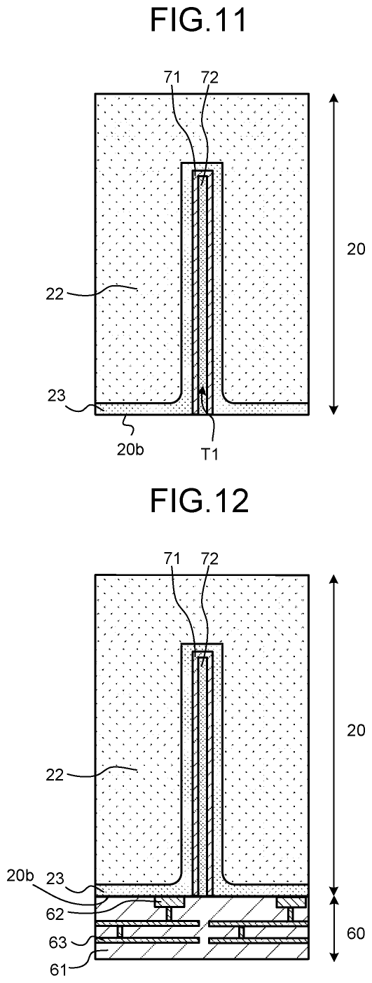

Next, an example of a process of manufacturing the light-receiving pixel 11 according to the first embodiment will be described with reference to FIGS. 11 to 18. FIGS. 11 to 18 are diagrams illustrating an example of the process of manufacturing the light-receiving pixel 11 according to the first embodiment of the present disclosure.

In the process of manufacturing the light-receiving pixel 11, as illustrated in FIG. 11, first, a trench T1 is formed on one main surface 20b side of the semiconductor layer 20 containing a first conductivity type impurity by a conventionally known method. Then, a second conductivity type impurity is diffused through an inner wall surface of the trench T1 and the main surface 20b by a conventionally known method.

As a result, a first impurity region 22 and a second impurity region 23 are formed inside the semiconductor layer 20. Note that the trench T1 is formed in a portion where the first separation region 24 and the second separation region 25 are to be disposed.

Next, an oxide film 71 is formed on the inner wall surface of the trench T1 by a conventionally known method, and a polysilicon film 72 is further formed by a conventionally known method so as to fill the remaining space of the trench T1.

Next, as illustrated in FIG. 12, a wiring layer 60 is formed on a surface of the main surface 20b of the semiconductor layer 20. The wiring layer 60 is configured by disposing a plurality of pixel transistors 62 and a plurality of wiring films 63 in an interlayer insulating film 61, and is formed by a conventionally known method.

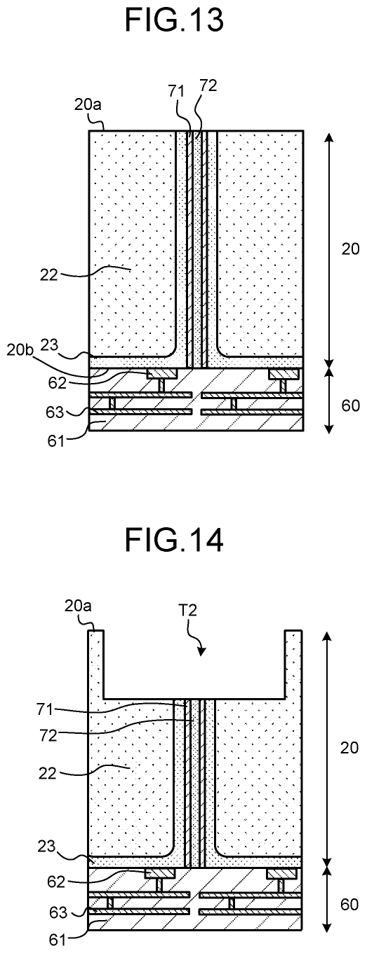

Next, as illustrated in FIG. 13, a surface of the semiconductor layer 20 on a side opposite to the main surface 20b is ground, and the semiconductor layer 20 is thinned such that the oxide film 71 and the polysilicon film 72 are exposed. As a result, the light incident surface 20a is formed on the semiconductor layer 20.

Next, as illustrated in FIG. 14, a trench T2 is formed in a portion where the third separation region 26 is to be disposed on the light incident surface 20a of the semiconductor layer 20 by a conventionally known method. Note that etching at the time of forming the trench T2 is performed under a condition that a selection ratio between silicon and the oxide film is low.

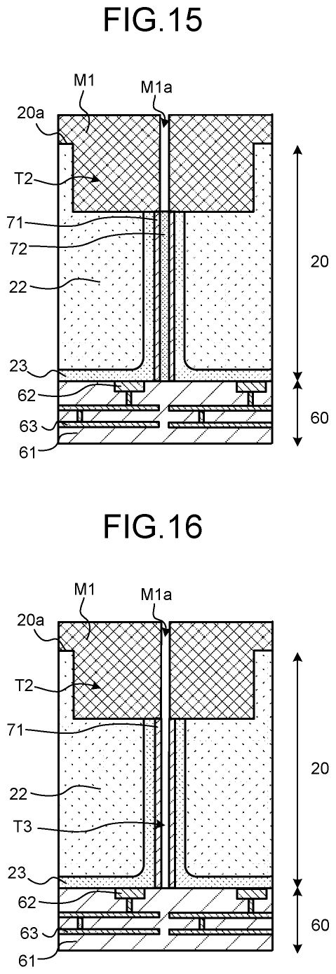

Next, as illustrated in FIG. 15, a mask M1 is formed by a conventionally known method so as to cover the light incident surface 20a of the semiconductor layer 20 and the trench T2. In addition, an opening M1a is formed in the mask M1 such that the polysilicon film 72 is exposed.

Next, as illustrated in FIG. 16, the polysilicon film 72 is etched by a conventionally known method through the opening M1a of the mask M1. As a result, a trench T3 is formed in the portion of the semiconductor layer 20 where the polysilicon film 72 was formed.

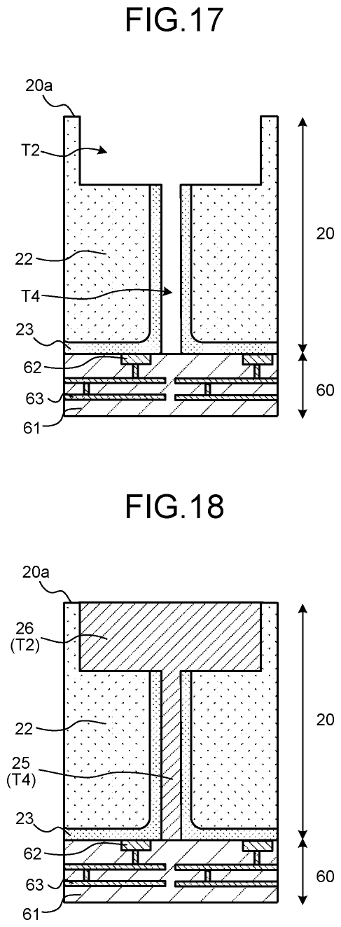

Next, as illustrated in FIG. 17, the mask M1 is removed by a conventionally known method, and the oxide film 71 is etched by a conventionally known method. As a result, a trench T4 is formed in a portion of the semiconductor layer 20 where the oxide film 71 and the polysilicon film 72 were formed.

Next, as illustrated in FIG. 18, a fixed charge film (not illustrated) is formed on inner wall surfaces of the trench T2 and the trench T4 by a conventionally known method, and a silicon oxide film is further formed by a conventionally known method so as to fill the remaining spaces of the trench T2 and the trench T4.

In the silicon oxide film, the silicon oxide film formed in the trench T2 constitutes the third separation region 26, and the silicon oxide film formed in the trench T4 constitutes the second separation region 25.

As described above, in the process of manufacturing the light-receiving pixel 11 according to the first embodiment, the third separation region 26 can be formed in the same step as the second separation region 25. In addition, although detailed description is omitted, the first separation region 24 can also be formed in a similar step to the second separation region 25.

That is, according to the first embodiment, in the process of manufacturing the light-receiving pixel 11, the third separation region 26 can be formed in the same step as the first separation region 24 and the second separation region 25.

Therefore, according to the first embodiment, since the process of manufacturing the pixel array unit 10 can be simplified, cost of manufacturing the solid-state imaging element 1 can be reduced.

In addition, in the first embodiment, by using the trench T1 formed before the step of forming the wiring layer 60, the second impurity region 23 can be formed not only at the bottom portion of the first impurity region 22 but also at the side portion of the first impurity region 22.

Therefore, according to the first embodiment, since the area of a PN junction surface of the photodiode 21 can be enlarged, a saturation signal charge amount of the photodiode 21 can be increased.

### Second Embodiment

In recent years, in a back irradiation type CMOS image sensor, there is a technique of causing light to be incident on a pair of photodiodes from the same on-chip lens to detect a phase difference.

In addition, by forming an impurity region in a partial region between the pair of photodiodes, the impurity region can function as an overflow path. Therefore, charge amounts accumulated in both photodiodes can be equal to each other.

However, in the above-described conventional technique, the same light obliquely incident on a light-receiving pixel disposed in a portion having a high image height may be incident on both of the pair of photodiodes via the impurity region disposed between the pair of photodiodes.

Then, the same light is incident on both of the pair of photodiodes, and a separation ratio between the pair of photodiodes thereby decreases. Therefore, accuracy of phase difference detection may decrease.

Therefore, it is expected to achieve a technique capable of overcoming the above-described problems and improving a separation ratio between the pair of photodiodes.

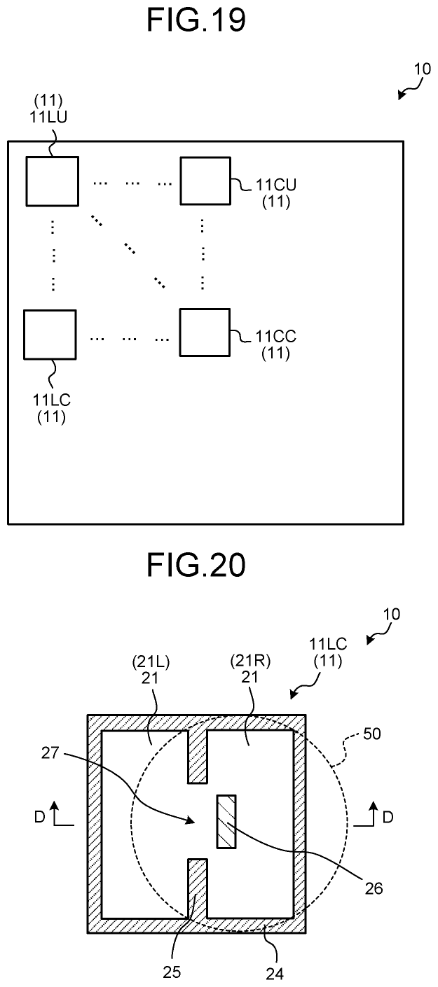

First, a detailed configuration of a pixel array unit 10 according to a second embodiment will be described with reference to FIGS. 19 to 23. FIG. 19 is a plan view for explaining an arrangement example of light-receiving pixels 11 of the pixel array unit 10 according to the second embodiment of the present disclosure.

As illustrated in FIG. 19, the pixel array unit 10 according to the second embodiment includes at least a light-receiving pixel 11CC located at an image height center, a light-receiving pixel 11LC located at a left center end portion, a light-receiving pixel 11CU located at an upper center end portion, and a light-receiving pixel 11LU located at an upper left end portion.

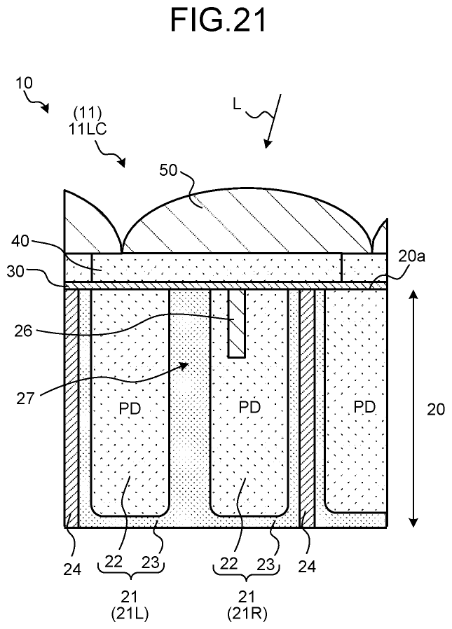

FIG. 20 is a plan view for explaining an arrangement example of the light-receiving pixel 11 and an on-chip lens 50 of the pixel array unit 10 according to the second embodiment of the present disclosure, and FIG. 21 is a cross-sectional view taken along line D-D illustrated in FIG. 20 as viewed in the direction of the arrow.

Note that FIGS. 20 and 21 illustrate an embodiment of the light-receiving pixel 11LC located at a left center end portion among the plurality of light-receiving pixels 11 arranged in the pixel array unit 10.

As illustrated in FIG. 21 and the like, the pixel array unit 10 includes a semiconductor layer 20, a planarizing film 30, a color filter 40, and the on-chip lens 50.

The semiconductor layer 20 contains, for example, silicon. The semiconductor layer 20 includes a plurality of photodiodes (PD) 21. The photodiode 21 is an example of a photoelectric conversion unit. Note that one light-receiving pixel 11 includes a pair of photodiodes 21 (hereinafter, also referred to as photodiodes 21L and 21R). In addition, the light-receiving pixel 11 has a substantially square shape in plan view, and the photodiode 21 has a substantially rectangular shape in plan view.

The photodiode 21 includes a first impurity region 22 containing a first conductivity type (for example, N type) impurity and a second impurity region 23 containing a second conductivity type (for example, P type) impurity.

The first impurity region 22 is disposed in a central portion of the photodiode 21, and the second impurity region 23 is disposed along a side portion and a bottom portion (a portion on a side opposite to a side on which light L is incident) of the first impurity region 22.

In addition, the light-receiving pixel 11 includes a first separation region 24, a second separation region 25, and a third separation region 26. As illustrated in FIG. 20, the first separation region 24 is disposed so as to surround the pair of photodiodes 21 in one light-receiving pixel 11.

In addition, as illustrated in FIG. 21, the first separation region 24 is disposed so as to penetrate the semiconductor layer 20. The first separation region 24 is made of, for example, a dielectric having a low refractive index, such as silicon oxide. As a result, the first separation region 24 can optically and electrically separate the plurality of light-receiving pixels 11 adjacent to each other.

As illustrated in FIG. 20, the second separation region 25 is disposed between the pair of photodiodes 21 adjacent to each other in one light-receiving pixel 11. In addition, similarly to the first separation region 24, the second separation region 25 is disposed so as to penetrate the semiconductor layer 20.

The second separation region 25 is made of, for example, a dielectric having a low refractive index, such as silicon oxide. As a result, the second separation region 25 can optically and electrically separate the plurality of photodiodes 21 adjacent to each other.

As described above, in the second embodiment, since the pair of photodiodes 21 can be separated from each other using the second separation region 25, a phase difference of incident light L can be detected using the pair of photodiodes 21.

In addition, in the second embodiment, the light-receiving pixel 11LC includes a second impurity region 27 disposed at a position different from the second separation region 25 in plan view between the pair of photodiodes 21 and containing a second conductivity type impurity. The second impurity region 27 is an example of an impurity region.

The second impurity region 27 functions as an overflow path between a photodiode 21L and a photodiode 21R. As a result, in the second embodiment, charge amounts accumulated in both the photodiodes 21L and 21R can be equal to each other.

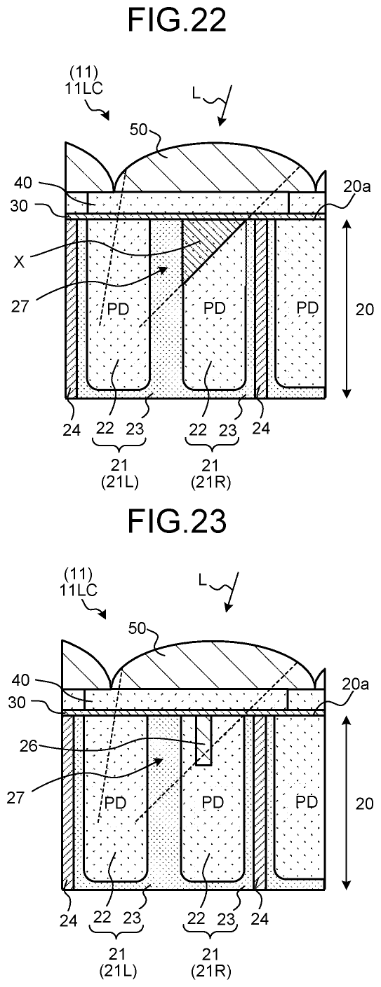

Meanwhile, by forming the second impurity region 27 between the pair of photodiodes 21, adverse effects as illustrated in FIG. 22 may occur. FIG. 22 is a cross-sectional view for explaining a state of light L incident on the light-receiving pixel 11LC in a reference example of the present disclosure.

As illustrated in FIG. 22, light L obliquely incident on the light-receiving pixel 11LC disposed in a portion having a high image height is incident on the photodiode 21L via a region X of the photodiode 21R and the second impurity region 27.

That is, the same light L obliquely incident on the light-receiving pixel 11LC disposed in a portion having a high image height may be incident on both the photodiodes 21L and 21R via the second impurity region 27.

Then, the same light L is incident on both the photodiodes 21L and 21R, and a separation ratio between the photodiodes 21L and 21R thereby decreases. Therefore, accuracy of phase difference detection may decrease.

Therefore, in the second embodiment, as illustrated in FIGS. 20 and 21, the problem is solved by disposing a third separation region 26 in the light-receiving pixel 11LC disposed in a portion having a high image height.

Specifically, as illustrated in FIG. 20, the third separation region 26 according to the second embodiment is disposed in a region surrounded by the first separation region 24. In addition, the third separation region 26 is disposed at a position where light L obliquely incident on the second impurity region 27 can be blocked (for example, a position closer to the image height center side with respect to the second impurity region 27).

In addition, the third separation region 26 is disposed so as to extend in the same direction (up-down direction in FIG. 20) as a direction in which the second separation region 25 extends and so as to be adjacent to the second impurity region 27 in plan view.

In addition, as in the first embodiment, the third separation region 26 is disposed from a light incident surface 20a of the semiconductor layer 20 to a middle of the semiconductor layer 20 (that is, so as not to penetrate the semiconductor layer 20). The third separation region 26 is made of, for example, the same material (a dielectric having a low refractive index) as that of the second separation region 25.

By disposing such a third separation region 26 in the light-receiving pixel 11LC, as illustrated in FIG. 23, most of light L incident on the photodiode 21L via the region X (see FIG. 22) of the photodiode 21R and the second impurity region 27 can be blocked by the third separation region 26. FIG. 23 is a cross-sectional view for explaining a state of light L incident on the light-receiving pixel 11LC according to the second embodiment of the present disclosure.

Therefore, according to the second embodiment, a separation ratio between the pair of photodiodes 21 can be improved.

In addition, in the second embodiment, the third separation region 26 is preferably made of the same material (for example, silicon oxide) as that of the first separation region 24 and the second separation region 25. As a result, in a process of manufacturing the light-receiving pixel 11, the third separation region 26 can be formed in the same step as the first separation region 24 and the second separation region 25.

Therefore, according to the second embodiment, since the process of manufacturing the pixel array unit 10 can be simplified, cost of manufacturing the solid-state imaging element 1 can be reduced.

Meanwhile, in the second embodiment, the third separation region 26 may be made of a material different from that of the first separation region 24 and the second separation region 25.

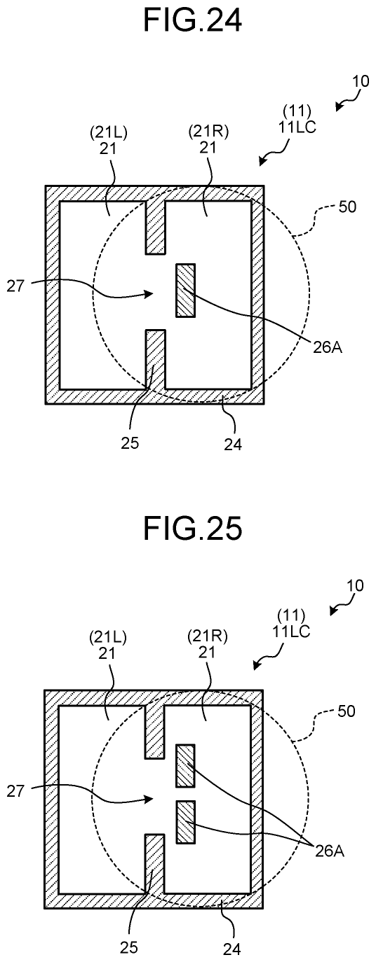

For example, as illustrated in FIG. 24, a third separation region 26A may be made of a material (for example, tantalum oxide or titanium oxide) having a higher refractive index than that of the first separation region 24 and the second separation region 25. FIG. 24 is a plan view for explaining another arrangement example of the light-receiving pixel 11LC and the on-chip lens 50 of the pixel array unit 10 according to the second embodiment of the present disclosure.

As a result, since a difference in refractive index between the third separation region 26A and the photodiode 21 can be reduced, it is possible to suppress light L incident on an end portion on a light incident side in the third separation region 26A from being largely scattered.

Therefore, according to the second embodiment, since scattered light caused by the third separation region 26A can be suppressed from leaking into another photodiode 21, occurrence of color mixing due to such scattered light can be suppressed.

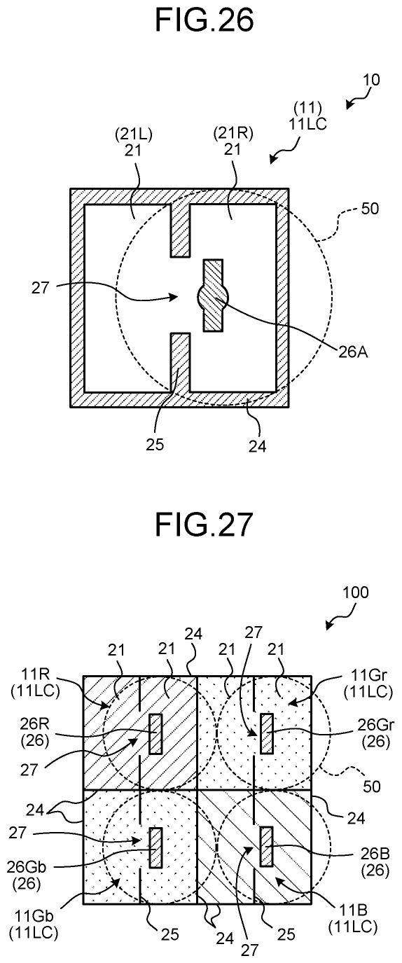

Note that the planar arrangement of the third separation region 26A using a material having a high refractive index is not limited to the example of FIG. 24. FIGS. 25 and 26 are each a plan view for explaining another arrangement example of the light-receiving pixel 11LC and the on-chip lens 50 of the pixel array unit 10 according to the second embodiment of the present disclosure.

For example, as illustrated in FIG. 25, the third separation region 26A may be divided into two, and as illustrated in FIG. 26, the third separation region 26A may have a shape in which a central portion of the third separation region 26A bulges more than both end portions.

Since this also makes it possible to reduce a difference in refractive index between the third separation region 26A and the photodiode 21, it is possible to suppress light L incident on an end portion on a light incident side in the third separation region 26A from being largely scattered.

Returning to FIGS. 20 and 21, description of other portions in the pixel array unit 10 will be continued. The planarizing film 30 is disposed on the light incident surface 20a of the semiconductor layer 20, and planarizes the light incident surface 20a. The planarizing film 30 is made of, for example, silicon oxide.

Note that, in the second embodiment, a fixed charge film (not illustrated) may be disposed between the photodiode 21 and each of the first separation region 24, the second separation region 25, and the planarizing film 30. Such a fixed charge film has a function of fixing a charge (here, a positive hole) to an interface between the photodiode 21 and each of the first separation region 24, the second separation region 25, and the planarizing film 30.

As a material of the fixed charge film, a high dielectric material having a large amount of fixed charges is preferably used. As the fixed charge film, for example, a similar material to the material of the fixed charge film according to the first embodiment described above can be used.

The color filter 40 is an optical filter that transmits light in a predetermined wavelength region among incident light beams L, and is disposed between the on-chip lens 50 and the planarizing film 30.

The on-chip lens 50 is disposed on a side where light L is incident on the semiconductor layer 20, and has a function of condensing light L toward a corresponding light-receiving pixel 11. The on-chip lens 50 is made of, for example, an organic material or silicon oxide.

In the second embodiment, as illustrated in FIG. 20 and the like, one on-chip lens 50 is disposed for one light-receiving pixel 11 (that is, one on-chip lens 50 is disposed for one pair of photodiodes 21).

In addition, in the second embodiment, as illustrated in FIG. 21 and the like, the color filter 40 and the on-chip lens 50 are disposed at positions closer to the image height center side with respect to the corresponding pair of photodiodes 21.

### Various Modifications of Second Embodiment

Next, various modifications of the second embodiment will be described with reference to FIGS. 27 to 35.

### Modification 1

FIG. 27 is a plan view for explaining an arrangement example of the light-receiving pixel 11 and the on-chip lens 50 of the pixel array unit 10 according to Modification 1 of the second embodiment of the present disclosure.

Note that FIG. 27 illustrates an embodiment of the light-receiving pixel 11LC located at a left center end portion among the plurality of light-receiving pixels 11 arranged in the pixel array unit 10 similarly to the second embodiment described above.

In Modification 1 of the second embodiment, as illustrated in FIG. 27, four light-receiving pixels 11LC constitute one light-receiving pixel group 100. The light-receiving pixel group 100 includes a red pixel 11R, a green pixel 11Gr, a green pixel 11Gb, and a blue pixel 11B.

The red pixel 11R has a color filter 40R (see FIG. 5), the green pixels 11Gr and 11Gb have color filters 40Gr and 40Gb (see FIG. 5), respectively, and the blue pixel 11B has a color filter 40B (see FIG. 5).

The color filter 40R is a color filter 40 that transmits light in a red wavelength region among incident light beams L, and the color filters 40Gr and 40Gb are color filters 40 that transmit light in a green wavelength region among incident light beams L. The color filter 40B is a color filter 40 that transmits light in a blue wavelength region among incident light beams L.

Furthermore, inside one light-receiving pixel group 100, the color filters 40R, 40Gr, 40Gb, and 40B are arranged in a regular color array (for example, Bayer array).

In addition, the red pixel 11R included in the light-receiving pixel group 100 receives red light that has passed through the color filter 40R, photoelectrically converts a charge amount corresponding to an incident light amount of the red light, and accumulates the photoelectrically converted charge amount inside the red pixel 11R.

Similarly, the green pixels 11Gr and 11Gb receive green light that has passed through the color filters 40Gr and 40Gb, photoelectrically converts a charge amount corresponding to an incident light amount of the green light, and accumulates the photoelectrically converted charge amount inside the green pixels 11Gr and 11Gb, respectively. In addition, the blue pixel 11B receives blue light that has passed through the color filter 40B, photoelectrically converts a charge amount corresponding to an incident light amount of the blue light, and accumulates the photoelectrically converted charge amount inside the blue pixel 11B.

As described above, in the light-receiving pixel group 100 according to Modification 1 of the second embodiment, light beams in two or more (three in the example of FIG. 27) wavelength regions are received by the individual light-receiving pixels 11, respectively.

In addition, in Modification 1 of the second embodiment, as illustrated in FIG. 27, each of the light-receiving pixels 11LC included in the same light-receiving pixel group 100 includes the third separation regions 26 adjacent to the second impurity region 27.

For example, the red pixel 11R includes a third separation region 26R, the green pixels 11Gr and 11Gb include third separation regions 26Gr and 26Gb, respectively, and the blue pixel 11B includes a third separation region 26B.

By disposing such a third separation region 26 in each of the light-receiving pixels 11LC included in the same light-receiving pixel group 100, a separation ratio between the pair of photodiodes 21 can be improved in each of the light-receiving pixels 11LC.

### Modification 2

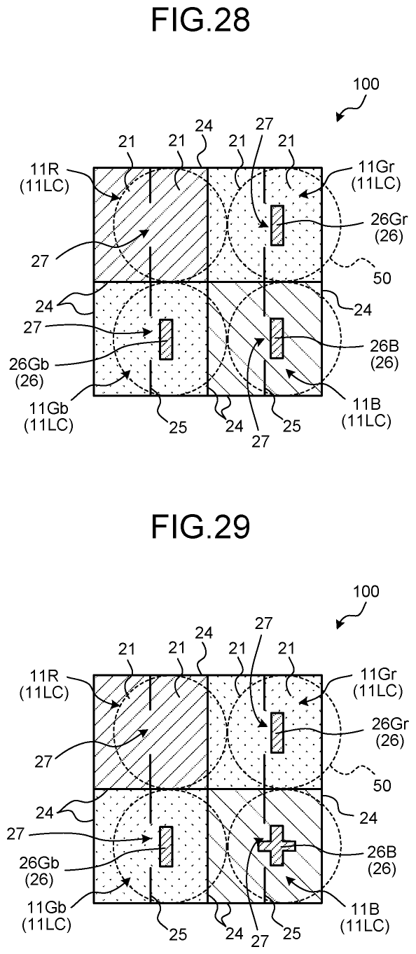

FIG. 28 is a plan view for explaining an arrangement example of the light-receiving pixel 11 and the on-chip lens 50 of the pixel array unit 10 according to Modification 2 of the second embodiment of the present disclosure.

Note that FIG. 28 illustrates an embodiment of the light-receiving pixel 11LC located at a left center end portion among the plurality of light-receiving pixels 11 arranged in the pixel array unit 10 similarly to the second embodiment and Modification 1 described above. In addition, in Modification 2 of the second embodiment, similarly to Modification 1 described above, four light-receiving pixels 11LC constitute one light-receiving pixel group 100.

Meanwhile, in Modification 2, unlike Modification 1 described above, the third separation region 26 is not disposed in the red pixel 11R. Since light in a red wavelength region incident on the red pixel 11R is largely scattered by the third separation region 26 as compared with light in a green or blue wavelength region, color mixing caused by the scattered light occurs to a considerable extent.

Therefore, in Modification 2, by not disposing the third separation region 26 in the red pixel 11R, occurrence of color mixing can be suppressed. In addition, in Modification 2, since the third separation region 26 is disposed in each of the green pixels 11Gr and 11Gb and the blue pixel 11B, a separation ratio between the pair of photodiodes 21 can be improved in each of the green pixels 11Gr and 11Gb and the blue pixel 11B.

That is, according to Modification 2 of the second embodiment, it is possible to achieve both suppression of color mixing and improvement of the separation ratio.

### Modification 3

FIG. 29 is a plan view for explaining an arrangement example of the light-receiving pixel 11 and the on-chip lens 50 of the pixel array unit 10 according to Modification 3 of the second embodiment of the present disclosure.

Note that FIG. 29 illustrates an embodiment of the light-receiving pixel 11LC located at a left center end portion among the plurality of light-receiving pixels 11 arranged in the pixel array unit 10 similarly to the second embodiment and Modifications 1 and 2 described above. In addition, in Modification 3 of the second embodiment, similarly to Modifications 1 and 2 described above, four light-receiving pixels 11LC constitute one light-receiving pixel group 100.

Meanwhile, in Modification 3, the planar shape of the third separation region 26B disposed in the blue pixel 11B is different from that of Modification 2 described above. Specifically, the third separation region 26B disposed in the blue pixel 11B has a substantially cross shape in plan view.

In other words, the third separation region 26B has a portion extending in the same direction (up-down direction in FIG. 29) as a direction in which the second separation region 25 extends in plan view, and a portion extending in a direction (left-right direction in FIG. 29) different from the direction in which the second separation region 25 extends.

As a result, light L incident on the cross-shaped third separation region 26B is scattered in various directions in the blue pixel 11B. Therefore, according to Modification 3 of the second embodiment, a saturation signal charge amount of the blue pixel 11B can be increased.

In addition, according to Modification 3 of the second embodiment, the third separation region 26 is disposed in each of the blue pixel 11B and the green pixels 11Gr and 11Gb, while the third separation region 26 is not disposed in the red pixel 11R. As a result, similarly to Modification 2 described above, it is possible to achieve both suppression of color mixing and improvement of the separation ratio.

### Modification 4

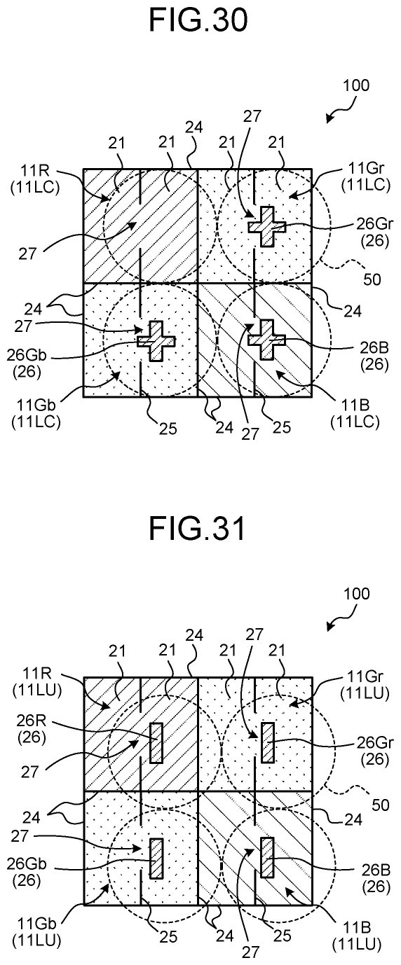

FIG. 30 is a plan view for explaining an arrangement example of the light-receiving pixel 11 and the on-chip lens 50 of the pixel array unit 10 according to Modification 4 of the second embodiment of the present disclosure.

Note that FIG. 30 illustrates an embodiment of the light-receiving pixel 11LC located at a left center end portion among the plurality of light-receiving pixels 11 arranged in the pixel array unit 10 similarly to the second embodiment and Modifications 1 to 3 described above. In addition, in Modification 4 of the second embodiment, similarly to Modifications 1 to 3 described above, four light-receiving pixels 11LC constitute one light-receiving pixel group 100.

Meanwhile, in Modification 4, the planar shape of the third separation region 26Gr disposed in the green pixels 11Gr and 11Gb is different from that of Modification 3 described above. Specifically, the third separation regions 26Gr and 26Gb disposed in the green pixels 11Gr and 11Gb, respectively each have a substantially cross shape in plan view.

As a result, light L incident on the cross-shaped third separation regions 26Gr and 26Gb is scattered in various directions in the green pixels 11Gr and 11Gb, respectively. Therefore, according to Modification 4 of the second embodiment, a saturation signal charge amount of each of the green pixels 11Gr and 11Gb can be increased.

In addition, according to Modification 4 of the second embodiment, since the cross-shaped third separation region 26B is disposed in the blue pixel 11B, a saturation signal charge amount of the blue pixel 11B can also be increased.

In addition, according to Modification 4 of the second embodiment, the third separation region 26 is disposed in each of the blue pixel 11B and the green pixels 11Gr and 11Gb, while the third separation region 26 is not disposed in the red pixel 11R. As a result, similarly to Modification 2 described above, it is possible to achieve both suppression of color mixing and improvement of the separation ratio.

### Modification 5

FIG. 31 is a plan view for explaining an arrangement example of the light-receiving pixel 11 and the on-chip lens 50 of the pixel array unit 10 according to Modification 5 of the second embodiment of the present disclosure.

Note that FIG. 31 illustrates an embodiment of the light-receiving pixel 11LU located at an upper left end portion among the plurality of light-receiving pixels 11 arranged in the pixel array unit 10 unlike the second embodiment and various modifications described above.

As illustrated in FIG. 31, in Modification 5 of the second embodiment, four light-receiving pixels 11LU constitute one light-receiving pixel group 100. The light-receiving pixel group 100 includes a red pixel 11R, a green pixel 11Gr, a green pixel 11Gb, and a blue pixel 11B.

The red pixel 11R has a color filter 40R (see FIG. 5), the green pixels 11Gr and 11Gb have color filters 40Gr and 40Gb (see FIG. 5), respectively, and the blue pixel 11B has a color filter 40B (see FIG. 5).

That is, in the light-receiving pixel group 100 according to Modification 5 of the second embodiment, light beams in two or more (three in the example of FIG. 31) wavelength regions are received by the individual light-receiving pixels 11, respectively.

In addition, in Modification 5 of the second embodiment, as illustrated in FIG. 31, each of the light-receiving pixels 11LU included in the same light-receiving pixel group 100 includes the third separation regions 26 adjacent to the second impurity region 27.

Specifically, the third separation region 26 according to Modification 5 of the second embodiment is disposed at a position where light L obliquely incident on the second impurity region 27 can be blocked (for example, a position closer to the image height center side with respect to the second impurity region 27).

As illustrated in FIG. 19, in the example of FIG. 31, since the image height center is disposed at the lower right of the light-receiving pixel group 100 in plan view, the third separation region 26 is disposed at a position closer to the lower right side with respect to the second impurity region 27. In addition, the third separation region 26 extends in the same direction (up-down direction in FIG. 31) as a direction in which the second separation region 25 extends.

By disposing such a third separation region 26 in each of the light-receiving pixels 11LU included in the same light-receiving pixel group 100, it is possible to suppress the same light L from being incident on both of the pair of photodiodes 21 via the second impurity region 27 in each of the light-receiving pixels 11LU.

Therefore, according to Modification 5 of the second embodiment, a separation ratio between the pair of photodiodes 21 can be improved in each of the light-receiving pixels 11LU.

### Modification 6

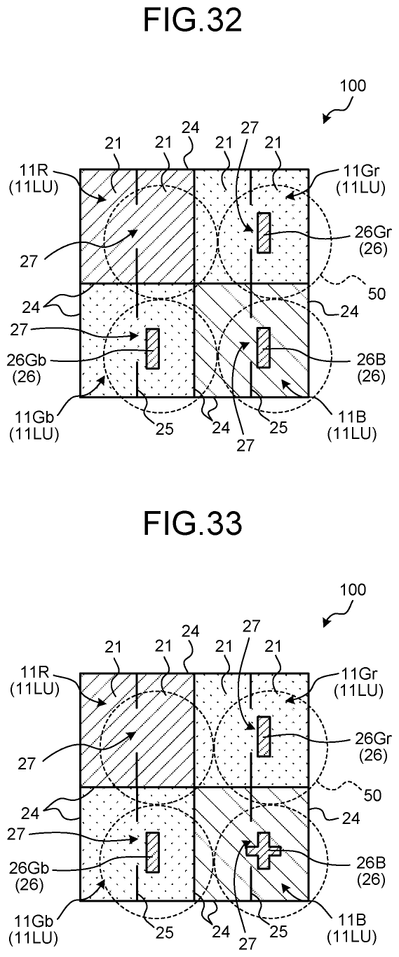

FIG. 32 is a plan view for explaining an arrangement example of the light-receiving pixel 11 and the on-chip lens 50 of the pixel array unit 10 according to Modification 6 of the second embodiment of the present disclosure.

Note that FIG. 32 illustrates an embodiment of the light-receiving pixel 11LU located at an upper left end portion among the plurality of light-receiving pixels 11 arranged in the pixel array unit 10 similarly to Modification 5 of the second embodiment described above. In addition, in Modification 2 of the second embodiment, similarly to Modification 5 described above, four light-receiving pixels 11LU constitute one light-receiving pixel group 100.

Meanwhile, in Modification 6, unlike Modification 5 described above, the third separation region 26 is not disposed in the red pixel 11R. Since light in a red wavelength region incident on the red pixel 11R is largely scattered by the third separation region 26 as compared with light in a green or blue wavelength region, color mixing caused by the scattered light occurs to a considerable extent.

Therefore, in Modification 6, by not disposing the third separation region 26 in the red pixel 11R, occurrence of color mixing can be suppressed. In addition, in Modification 6, since the third separation region 26 is disposed in each of the green pixels 11Gr and 11Gb and the blue pixel 11B, a separation ratio between the pair of photodiodes 21 can be improved in each of the green pixels 11Gr and 11Gb and the blue pixel 11B.

That is, according to Modification 6 of the second embodiment, it is possible to achieve both suppression of color mixing and improvement of the separation ratio.

### Modification 7

FIG. 33 is a plan view for explaining an arrangement example of the light-receiving pixel 11 and the on-chip lens 50 of the pixel array unit 10 according to Modification 7 of the second embodiment of the present disclosure.

Note that FIG. 33 illustrates an embodiment of the light-receiving pixel 11LU located at an upper left end portion among the plurality of light-receiving pixels 11 arranged in the pixel array unit 10 similarly to Modifications 5 and 6 of the second embodiment described above. In addition, in Modification 7 of the second embodiment, similarly to Modifications 5 and 6 described above, four light-receiving pixels 11LU constitute one light-receiving pixel group 100.

Meanwhile, in Modification 7, the planar shape of the third separation region 26B disposed in the blue pixel 11B is different from that of Modification 6 described above. Specifically, the third separation region 26B disposed in the blue pixel 11B has a substantially cross shape in plan view.

As a result, light L incident on the cross-shaped third separation region 26B is scattered in various directions in the blue pixel 11B. Therefore, according to Modification 7 of the second embodiment, a saturation signal charge amount of the blue pixel 11B can be increased.

In addition, according to Modification 7 of the second embodiment, the third separation region 26 is disposed in each of the blue pixel 11B and the green pixels 11Gr and 11Gb, while the third separation region 26 is not disposed in the red pixel 11R. As a result, similarly to Modification 6 described above, it is possible to achieve both suppression of color mixing and improvement of the separation ratio.

### Modification 8

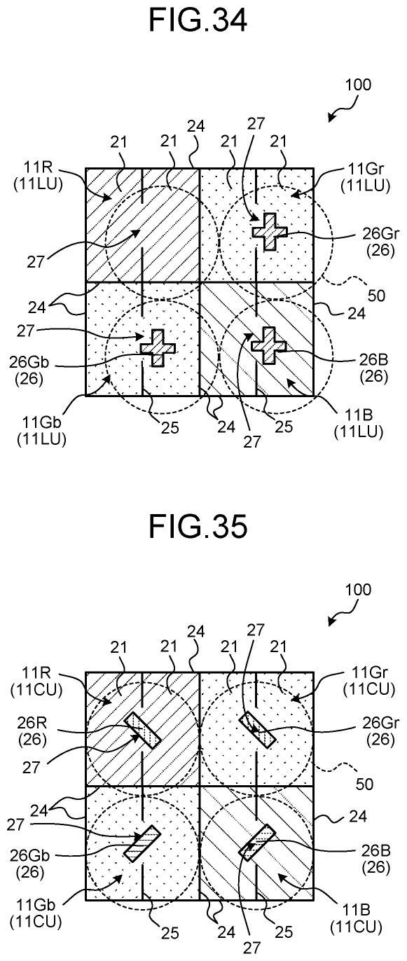

FIG. 34 is a plan view for explaining an arrangement example of the light-receiving pixel 11 and the on-chip lens 50 of the pixel array unit 10 according to Modification 8 of the second embodiment of the present disclosure.

Note that FIG. 34 illustrates an embodiment of the light-receiving pixel 11LU located at an upper left end portion among the plurality of light-receiving pixels 11 arranged in the pixel array unit 10 similarly to Modifications 5 to 7 of the second embodiment described above. In addition, in Modification 8 of the second embodiment, similarly to Modifications 5 to 7 described above, four light-receiving pixels 11LU constitute one light-receiving pixel group 100.

Meanwhile, in Modification 8, the planar shape of the third separation region 26Gr disposed in the green pixels 11Gr and 11Gb is different from that of Modification 7 described above. Specifically, the third separation regions 26Gr and 26Gb disposed in the green pixels 11Gr and 11Gb, respectively each have a substantially cross shape in plan view.

As a result, light L incident on the cross-shaped third separation regions 26Gr and 26Gb is scattered in various directions in the green pixels 11Gr and 11Gb, respectively. Therefore, according to Modification 8 of the second embodiment, a saturation signal charge amount of each of the green pixels 11Gr and 11Gb can be increased.

In addition, according to Modification 8 of the second embodiment, since the cross-shaped third separation region 26B is disposed in the blue pixel 11B, a saturation signal charge amount of the blue pixel 11B can also be increased.

In addition, according to Modification 8 of the second embodiment, the third separation region 26 is disposed in each of the blue pixel 11B and the green pixels 11Gr and 11Gb, while the third separation region 26 is not disposed in the red pixel 11R. As a result, similarly to Modification 6 described above, it is possible to achieve both suppression of color mixing and improvement of the separation ratio.

### Modification 9

FIG. 35 is a plan view for explaining an arrangement example of the light-receiving pixel 11 and the on-chip lens 50 of the pixel array unit 10 according to Modification 9 of the second embodiment of the present disclosure.

Note that FIG. 35 illustrates an embodiment of the light-receiving pixel 11CU located at an upper center end portion among the plurality of light-receiving pixels 11 arranged in the pixel array unit 10 unlike the second embodiment and various modifications described above.

As illustrated in FIG. 35, in Modification 9 of the second embodiment, four light-receiving pixels 11CU constitute one light-receiving pixel group 100. The light-receiving pixel group 100 includes a red pixel 11R, a green pixel 11Gr, a green pixel 11Gb, and a blue pixel 11B.

The red pixel 11R has a color filter 40R (see FIG. 5), the green pixels 11Gr and 11Gb have color filters 40Gr and 40Gb (see FIG. 5), respectively, and the blue pixel 11B has a color filter 40B (see FIG. 5).

That is, in the light-receiving pixel group 100 according to Modification 9 of the second embodiment, light beams in two or more (three in the example of FIG. 35) wavelength regions are received by the individual light-receiving pixels 11, respectively.

In addition, in Modification 9 of the second embodiment, as illustrated in FIG. 35, each of the light-receiving pixels 11CU included in the same light-receiving pixel group 100 includes the third separation regions 26 disposed so as to overlap with the second impurity region 27. In addition, the third separation region 26 extends in a direction (oblique direction in FIG. 35) intersecting with a direction in which the second separation region 25 extends.

As illustrated in FIG. 19 described above, in the example of FIG. 35, since the image height center is disposed below the light-receiving pixel group 100 in plan view, obliquely incident light L is basically not incident on both of the pair of photodiodes 21 via the second impurity region 27.

However, even in such a case, by disposing the third separation region 26 as illustrated in FIG. 35, a separation ratio between the pair of photodiodes 21 can be improved in each of the light-receiving pixels 11CU.

Note that, in the second embodiment and various modifications described above, the planar shape of the third separation region 26 disposed in the light-receiving pixel 11 is not limited to the examples of the present disclosure, and the third separation region 26 may have various planar shapes.

### EFFECTS

The solid-state imaging element 1 according to the first embodiment includes the plurality of light-receiving pixels 11 arranged in a matrix inside the semiconductor layer 20. In addition, the light-receiving pixel 11 includes the pair of photoelectric conversion units (photodiodes 21), the first separation region 24, the second separation region 25, and the third separation region 26. The pair of photoelectric conversion units (photodiodes 21) are disposed adjacent to each other. The first separation region 24 is disposed so as to surround the pair of photoelectric conversion units (photodiodes 21) and is disposed so as to penetrate the semiconductor layer 20. The second separation region 25 is disposed between the pair of photoelectric conversion units (photodiodes 21) and is disposed so as to penetrate the semiconductor layer 20. The third separation region 26 is disposed in a region surrounded by the first separation region 24 and is disposed from the light incident surface 20a of the semiconductor layer 20 to a middle of the semiconductor layer 20.

This can improve the non-uniformity of color mixing in the pixel array unit 10.

In addition, in the solid-state imaging element 1 according to the first embodiment, the third separation region 26 is disposed so as to straddle the second separation region 25 in plan view.

This can improve the non-uniformity of color mixing in the pixel array unit 10.

In addition, the solid-state imaging element 1 according to the first embodiment includes the light-receiving pixel group 100 including the plurality of light-receiving pixels 11 that receives light in two or more wavelength regions. In addition, in the plurality of light-receiving pixels 11 included in the same light-receiving pixel group 100, the third separation regions 26 having different positions and/or different shapes are disposed, respectively.

This can improve the non-uniformity of color mixing in the pixel array unit 10.

In addition, in the solid-state imaging element 1 according to the first embodiment, in the plurality of light-receiving pixels 11 having different image heights, the third separation regions 26 having different positions and/or different shapes are disposed, respectively.

This can improve the non-uniformity of color mixing in the pixel array unit 10.

In addition, the solid-state imaging element 1 according to the second embodiment includes the plurality of light-receiving pixels 11 arranged in a matrix inside the semiconductor layer 20. In addition, the light-receiving pixel 11 includes the pair of photoelectric conversion units (photodiodes 21), the first separation region 24, the second separation region 25, the impurity region (second impurity region 27), and the third separation region 26. The pair of photoelectric conversion units (photodiodes 21) are disposed adjacent to each other. The first separation region 24 is disposed so as to surround the pair of photoelectric conversion units (photodiodes 21) and is disposed so as to penetrate the semiconductor layer 20. The second separation region 25 is disposed between the pair of photoelectric conversion units (photodiodes 21) and is disposed so as to penetrate the semiconductor layer 20. The impurity region (second impurity region 27) is disposed at a position different from the second separation region 25 in plan view between the pair of photoelectric conversion units (photodiodes 21). The third separation region 26 is disposed in a region surrounded by the first separation region 24 and is disposed from the light incident surface 20a of the semiconductor layer 20 to a middle of the semiconductor layer 20.

This can improve a separation ratio between the pair of photodiodes 21.

In addition, in the solid-state imaging element 1 according to the second embodiment, the third separation region 26 is disposed adjacent to the impurity region (second impurity region 27) in plan view.

This can improve a separation ratio between the pair of photodiodes 21.

In addition, in the solid-state imaging element 1 according to the second embodiment, the third separation region 26 has a substantially cross shape in plan view.

As a result, it is possible to achieve both suppression of color mixing and improvement of the separation ratio.

In addition, in the solid-state imaging element 1 according to the second embodiment, in the plurality of light-receiving pixels 11 having different image heights, the third separation regions 26 having different positions and/or different shapes are disposed, respectively.

This can improve a separation ratio between the pair of photodiodes 21.

### Electronic Device

Note that the present disclosure is not limited to application to a solid-state imaging element. That is, the present disclosure is applicable to all electronic devices each including a solid-state imaging element, such as a camera module, an imaging device, a portable terminal device having an imaging function, or a copying machine using a solid-state imaging element in an image reading unit, in addition to the solid-state imaging element.

Examples of such an imaging device include a digital still camera and a video camera. Examples of such a portable terminal device having an imaging function include a smartphone and a tablet terminal.

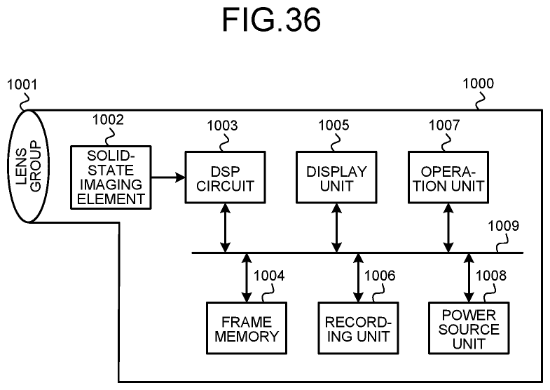

FIG. 36 is a block diagram illustrating a configuration example of an imaging device as an electronic device 1000 to which the technique according to the present disclosure is applied. The electronic device 1000 in FIG. 36 is an electronic device, for example, an imaging device such as a digital still camera or a video camera, or a portable terminal device such as a smartphone or a tablet terminal.

In FIG. 36, the electronic device 1000 includes a lens group 1001, a solid-state imaging element 1002, a DSP circuit 1003, a frame memory 1004, a display unit 1005, a recording unit 1006, an operation unit 1007, and a power source unit 1008.

In the electronic device 1000, the DSP circuit 1003, the frame memory 1004, the display unit 1005, the recording unit 1006, the operation unit 1007, and the power source unit 1008 are connected to each other via a bus line 1009.

The lens group 1001 captures incident light (image light) from a subject and forms an image on an imaging surface of the solid-state imaging element 1002. The solid-state imaging element 1002 corresponds to the solid-state imaging element 1 according to each of the above-described embodiments, and converts the amount of incident light imaged on the imaging surface by the lens group 1001 into an electrical signal in units of pixels and outputs the electrical signal as a pixel signal.

The DSP circuit 1003 is a camera signal processing circuit that processes a signal supplied from the solid-state imaging element 1002. The frame memory 1004 temporarily holds image data processed by the DSP circuit 1003 in units of frames.

The display unit 1005 is constituted by, for example, a panel type display device such as a liquid crystal panel or an organic electro luminescence (EL) panel, and displays a moving image or a still image imaged by the solid-state imaging element 1002. The recording unit 1006 records image data of a moving image or a still image imaged by the solid-state imaging element 1002 on a recording medium such as a semiconductor memory or a hard disk.

The operation unit 1007 issues operation commands for various functions of the electronic device 1000 in response to an operation by a user. The power source unit 1008 appropriately supplies various power sources serving as operation power sources of the DSP circuit 1003, the frame memory 1004, the display unit 1005, the recording unit 1006, and the operation unit 1007 to these supply targets.

In the electronic device 1000 configured as described above, signal quality can be improved by applying the solid-state imaging element 1 of each of the above-described embodiments as the solid-state imaging element 1002.

Although the embodiments of the present disclosure have been described above, the technical scope of the present disclosure is not limited to the above-described embodiments as they are, and various modifications can be made without departing from the gist of the present disclosure. In addition, components of different embodiments and modifications may be appropriately combined with each other.

In addition, the effects described here are merely examples and are not limited, and other effects may be exhibited.

Note that the present technique can also have the following configurations.

(1)

A solid-state imaging element comprising a plurality of light-receiving pixels arranged in a matrix inside a semiconductor layer, wherein

each of the light-receiving pixels includes:

a pair of photoelectric conversion units disposed adjacent to each other;

a first separation region disposed so as to surround the pair of photoelectric conversion units and disposed so as to penetrate the semiconductor layer;

a second separation region disposed between the pair of photoelectric conversion units and disposed so as to penetrate the semiconductor layer; and

a third separation region disposed in a region surrounded by the first separation region and disposed from a light incident surface of the semiconductor layer to a middle of the semiconductor layer.

(2)

The solid-state imaging element according to the above (1), wherein

the third separation region is disposed so as to straddle the second separation region in plan view.

(3)

The solid-state imaging element according to the above (1) or (2), comprising a light-receiving pixel group including the plurality of light-receiving pixels that receives light in two or more wavelength regions, wherein

in the plurality of light-receiving pixels included in the same light-receiving pixel group, the third separation regions having at least one of different positions and different shapes are disposed, respectively.

(4)

The solid-state imaging element according to to any one of the above (1) to (3), wherein

in the plurality of light-receiving pixels having different image heights, the third separation regions having at least one of different positions and different shapes are disposed, respectively.

(5)

An electronic device comprising:

a solid-state imaging element;

an optical system that captures incident light from a subject and forms an image on an imaging surface of the solid-state imaging element; and

a signal processing circuit that performs processing on an output signal from the solid-state imaging element, wherein

the solid-state imaging element includes a plurality of light-receiving pixels arranged in a matrix inside a semiconductor layer, and

each of the light-receiving pixels includes:

a pair of photoelectric conversion units disposed adjacent to each other;

a first separation region disposed so as to surround the pair of photoelectric conversion units and disposed so as to penetrate the semiconductor layer;

a second separation region disposed between the pair of photoelectric conversion units and disposed so as to penetrate the semiconductor layer; and

a third separation region disposed in a region surrounded by the first separation region and disposed from a light incident surface of the semiconductor layer to a middle of the semiconductor layer.

(6)

The electronic device according to the above (5), wherein

the third separation region is disposed so as to straddle the second separation region in plan view.

(7)

The electronic device according to the above (5) or (6), comprising a light-receiving pixel group including the plurality of light-receiving pixels that receives light in two or more wavelength regions, in which

in the plurality of light-receiving pixels included in the same light-receiving pixel group, the third separation regions having different positions and/or different shapes are disposed, respectively.

(8)

The electronic device according to any one of the above (5) to (7), wherein

in the plurality of light-receiving pixels having different image heights, the third separation regions having different positions and/or different shapes are disposed, respectively.

(9)

A solid-state imaging element including a plurality of light-receiving pixels arranged in a matrix inside a semiconductor layer, in which

each of the light-receiving pixels includes:

a pair of photoelectric conversion units disposed adjacent to each other;

a first separation region disposed so as to surround the pair of photoelectric conversion units and disposed so as to penetrate the semiconductor layer;

a second separation region disposed between the pair of photoelectric conversion units and disposed so as to penetrate the semiconductor layer;

an impurity region disposed at a position different from the second separation region in plan view between the pair of photoelectric conversion units; and

a third separation region disposed in a region surrounded by the first separation region and disposed from a light incident surface of the semiconductor layer to a middle of the semiconductor layer.

(10)

The solid-state imaging element according to the above (9), wherein

the third separation region is disposed adjacent to the impurity region in plan view.

(11)

The solid-state imaging element according to the above (9) or (10), wherein

the third separation region has a substantially cross shape in plan view.

(12)

The solid-state imaging element according to any one of the above (9) to (11), wherein

in the plurality of light-receiving pixels having different image heights, the third separation regions having different positions and/or different shapes are disposed, respectively.

(13)

An electronic device including:

a solid-state imaging element;

an optical system that captures incident light from a subject and forms an image on an imaging surface of the solid-state imaging element; and

a signal processing circuit that performs processing on an output signal from the solid-state imaging element, in which

the solid-state imaging element includes a plurality of light-receiving pixels arranged in a matrix inside a semiconductor layer, and

each of the light-receiving pixels includes:

a pair of photoelectric conversion units disposed adjacent to each other;

a first separation region disposed so as to surround the pair of photoelectric conversion units and disposed so as to penetrate the semiconductor layer;

a second separation region disposed between the pair of photoelectric conversion units and disposed so as to penetrate the semiconductor layer;

an impurity region disposed at a position different from the second separation region in plan view between the pair of photoelectric conversion units; and

a third separation region disposed in a region surrounded by the first separation region and disposed from a light incident surface of the semiconductor layer to a middle of the semiconductor layer.

(14)

The electronic device according to the above (13), wherein

the third separation region is disposed adjacent to the impurity region in plan view.

(15)

The electronic device according to the above (13) or (14), wherein

the third separation region has a substantially cross shape in plan view.

(16)

The electronic device according to any one of the above (13) to (15), wherein

in the plurality of light-receiving pixels having different image heights, the third separation regions having different positions and/or different shapes are disposed, respectively.

### REFERENCE SIGNS LIST

1 SOLID-STATE IMAGING ELEMENT
10 PIXEL ARRAY UNIT
11 LIGHT-RECEIVING PIXEL
20 SEMICONDUCTOR LAYER
20a LIGHT INCIDENT SURFACE
21 PHOTODIODE (EXAMPLE OF PHOTOELECTRIC CONVERSION UNIT)
24 FIRST SEPARATION REGION
25 SECOND SEPARATION REGION
26 THIRD SEPARATION REGION
27 SECOND IMPURITY REGION (EXAMPLE OF IMPURITY REGION)
100 LIGHT-RECEIVING PIXEL GROUP
1000 ELECTRONIC DEVICE

1. A solid-state imaging element comprising a plurality of light-receiving pixels arranged in a matrix inside a semiconductor layer, wherein
each of the light-receiving pixels includes:
a pair of photoelectric conversion units disposed adjacent to each other;
a first separation region disposed so as to surround the pair of photoelectric conversion units and disposed so as to penetrate the semiconductor layer;
a second separation region disposed between the pair of photoelectric conversion units and disposed so as to penetrate the semiconductor layer; and
a third separation region disposed in a region surrounded by the first separation region and disposed from a light incident surface of the semiconductor layer to a middle of the semiconductor layer.

2. The solid-state imaging element according to claim 1, wherein
the third separation region is disposed so as to straddle the second separation region in plan view.

3. The solid-state imaging element according to claim 1, comprising a light-receiving pixel group including the plurality of light-receiving pixels that receives light in two or more wavelength regions, wherein
in the plurality of light-receiving pixels included in the same light-receiving pixel group, the third separation regions having at least one of different positions and different shapes are disposed, respectively.

4. The solid-state imaging element according to claim 1, wherein
in the plurality of light-receiving pixels having different image heights, the third separation regions having at least one of different positions and different shapes are disposed, respectively.

5. An electronic device comprising:
a solid-state imaging element;
an optical system that captures incident light from a subject and forms an image on an imaging surface of the solid-state imaging element; and
a signal processing circuit that performs processing on an output signal from the solid-state imaging element, wherein
the solid-state imaging element includes a plurality of light-receiving pixels arranged in a matrix inside a semiconductor layer, and
each of the light-receiving pixels includes:
a pair of photoelectric conversion units disposed adjacent to each other;
a first separation region disposed so as to surround the pair of photoelectric conversion units and disposed so as to penetrate the semiconductor layer;
a second separation region disposed between the pair of photoelectric conversion units and disposed so as to penetrate the semiconductor layer; and
a third separation region disposed in a region surrounded by the first separation region and disposed from a light incident surface of the semiconductor layer to a middle of the semiconductor layer.
